(19) United States
(12) Patent Application Publication
(10) Pub. No.: US 2026/0107497 A1
(43) Pub. Date: Apr. 16, 2026

(54) SEMICONDUCTOR DEVICE

(71) Applicant: SAMSUNG ELECTRONICS CO., LTD., Suwon-si (KR)

(72) Inventors: Wookhyun KWON, Suwon-si (KR); Younggwon KIM, Suwon-si (KR); Jina KIM, Suwon-si (KR); Jongpil KIM, Suwon-si (KR); Yunyeong YI, Suwon-si (KR); Byounghak HONG, Suwon-si (KR)

(73) Assignee: SAMSUNG ELECTRONICS CO., LTD., Suwon-si (KR)

(21) Appl. No.: 19/093,436

(22) Filed: Mar. 28, 2025

(30) Foreign Application Priority Data
Oct. 14, 2024 (KR) 10-2024-0139480

(51) Int. Cl. H10D 30/62

(52) U.S. Cl. CPC H10D 30/6219

(57) ABSTRACT

A semiconductor device includes: an active region extending in a first direction; a gate structure extending in a second direction; a first source/drain region and a second source/drain region; a plurality of channel layers; and contact plugs. Each of the first source/drain region and the second source/drain region includes a plurality of protrusion portions including a first protrusion portion, a second protrusion portion, and a third protrusion portion. A first distance between the first protrusion portion of the first source/drain region and the first protrusion portion of the second source/drain region is less than a second distance between the second protrusion portion of the first source/drain region and the second protrusion portion of the second source/drain region and a third distance between the third protrusion portion of the first source/drain region and the third protrusion portion of the second source/drain region, respectively.

### CROSS-REFERENCE TO RELATED APPLICATION

This application claims benefit of priority to Korean Patent Application No. 10-2024-0139480 filed on Oct. 14, 2024, in the Korean Intellectual Property Office, the disclosure of which is incorporated herein by reference in its entirety.

### TECHNICAL FIELD

The present disclosure relates to a semiconductor device, and more particularly to a semiconductor device having improved reliability obtained by controlling an inner gate length through a hat-shaped or Dumbbell-shaped source/drain region.

### BACKGROUND

As the demand for the implementation of high performance, high speed, and/or multifunctionality of semiconductor devices increases, the integration of semiconductor devices has increased. In accordance with the trend toward high integration of semiconductor devices, semiconductor devices having a BackSide Power Delivery Network (BSPDN) structure in which power rails are disposed on the backside of the wafer have been developed. In addition, efforts are being made to develop semiconductor devices including FinFETs having a three-dimensional channel structure to overcome the limitations of operating characteristics due to the size reduction of planar metal oxide semiconductor FET (MOSFET).

### SUMMARY

An aspect of the present disclosure is to provide a semiconductor device having improved integration and reliability.

A semiconductor device according to example embodiments may include: an active region extending in a first direction; a gate structure disposed on the active region, the gate structure extending in a second direction perpendicular to the first direction; a first source/drain region and a second source/drain region disposed on opposite sides of the gate structure along the first direction; a plurality of channel layers disposed spaced apart from each other in a vertical direction that is perpendicular to the first direction and the second direction, the plurality of channel layers including a first channel layer, a second channel layer, and a third channel layer arranged sequentially along the vertical direction, each of the plurality of channel layers being surrounded by the gate structure in a plane perpendicular to the first direction; a first contact plug electrically connected to the first source/drain region; and a second contact plug electrically connected to the second source/drain region, wherein each of the first source/drain region and the second source/drain region includes a plurality of protrusion portions comprising: a first protrusion portion disposed below the first channel layer, the first protrusion portion extending toward the gate structure along the first direction, a second protrusion portion disposed below the second channel layer, the second protrusion extending toward the gate structure along the first direction, and a third protrusion portion disposed below the third channel layer, the third protrusion extending toward the gate structure along the first direction, and wherein a first distance along the first direction between the first protrusion portion of the first source/drain region and the first protrusion portion of the second source/drain region is less than a second distance along the first direction between the second protrusion portion of the first source/drain region and the second protrusion portion of the second source/drain region, and the first distance is less than a third distance along the first direction between the third protrusion portion of the first source/drain region and the third protrusion portion of the second source/drain region.

A semiconductor device according to example embodiments may include: a gate structure; a plurality of channel layers disposed spaced apart from each other in a vertical direction, the plurality of channel layers including a lowermost channel layer, an intermediate channel layer, and an uppermost channel layer arranged sequentially in the vertical direction, each of the plurality of channel layers being surrounded by the gate structure; and a source/drain region on one side of the gate structure and connected to the plurality of channel layers, wherein the source/drain region includes a plurality of protrusion portions including: a lowermost protrusion portion extending in a first horizontal direction toward the gate structure, the lowermost protrusion portion disposed below the lowermost channel layer; an intermediate protrusion portion extending in the first horizontal direction, the intermediate protrusion portion disposed between the lowermost channel layer and the intermediate channel layer; and an uppermost protrusion portion extending in the first horizontal direction, the uppermost protrusion portion disposed between the intermediate channel layer and the uppermost channel layer; and a first width of the lowermost protrusion portion in the first horizontal direction is greater than a second width of the intermediate protrusion portion in the first horizontal direction.

A semiconductor device according to example embodiments may include: a gate structure; a plurality of channel layers including a first channel layer, a second channel layer, and a third channel layer arranged sequentially in a vertical direction, the uppermost channel layer being disposed adjacent to the gate structure, each of the plurality of channel layers being surrounded by the gate structure; a source/drain region on at least one side of the gate structure and connected to the plurality of channel layers; and a backside contact plug connected to the source/drain region, wherein the gate structure includes: a first gate portion disposed below the first channel layer in the vertical direction; a second gate portion disposed between the first channel layer and the second channel layer in the vertical direction; a third gate portion disposed between the second channel layer and the third channel layer in the vertical direction; and a fourth gate portion disposed on the third channel layer in the vertical direction, wherein a first gate width of the first gate portion in a first direction perpendicular to the vertical direction is less than a second gate width of the second gate portion in the first direction and a third gate width of the third gate portion in the first direction, respectively.

A source/drain connected to a plurality of channel layers may include protrusion portions in a lower portion of a gate structure and/or an upper portion the gate structure, thereby providing a semiconductor device having improved reliability.

Advantages and effects of the present disclosure are not limited to the foregoing content and may be more easily understood in the process of describing example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view illustrating a semiconductor device according to example embodiments;

FIG. 2 includes schematic cross-sectional views illustrating a semiconductor device according to example embodiments;

FIG. 3 is a schematic partial enlarged view illustrating a semiconductor device according to example embodiments;

FIG. 4A includes cross-sectional views illustrating a semiconductor device according to example embodiments;

FIG. 4B is a partially enlarged view illustrating a semiconductor device according to example embodiments;

FIG. 5A includes cross-sectional views illustrating a semiconductor device according to example embodiments;

FIG. 5B is a partially enlarged view illustrating a semiconductor device according to example embodiments;

FIG. 6A includes cross-sectional views illustrating a semiconductor device according to example embodiments;

FIG. 6B is a partially enlarged view illustrating a semiconductor device according to example embodiments;

FIG. 7A includes cross-sectional views illustrating a semiconductor device according to example embodiments;

FIG. 7B is a partially enlarged view illustrating a semiconductor device according to example embodiments;

FIG. 8A includes cross-sectional views illustrating a semiconductor device according to example embodiments;

FIG. 8B is a partially enlarged view illustrating a semiconductor device according to example embodiments;

FIG. 9A includes cross-sectional views illustrating a semiconductor device according to example embodiments;

FIG. 9B is a partially enlarged view illustrating a semiconductor device according to example embodiments;

FIG. 10 includes cross-sectional views illustrating a semiconductor device according to example embodiments;

FIG. 11 includes cross-sectional views illustrating a semiconductor device according to example embodiments;

FIGS. 12, 13, 14, 15A, 16A, 17, 18, 19, 20A, 21A, 22, 23, 24, 25, 26, 27, and 28 are cross-sectional views illustrating a method of manufacturing a semiconductor device according to example embodiments of the present disclosure; and

FIGS. 15B, 16B, 20B, and 21B are partially enlarged views illustrating a method of manufacturing a semiconductor device according to example embodiments of the present disclosure according to a process order.

### DETAILED DESCRIPTION

Hereinafter, example embodiments of the present disclosure will be described with reference to the accompanying drawings. Unless otherwise specified, in the present disclosure, it may be understood that the expressions such as “on,” “above,” “upper,” “below,” “beneath,” “lower,” and “side surface,” are merely indicated based on drawings, and may actually vary depending on the direction in which the components are disposed.

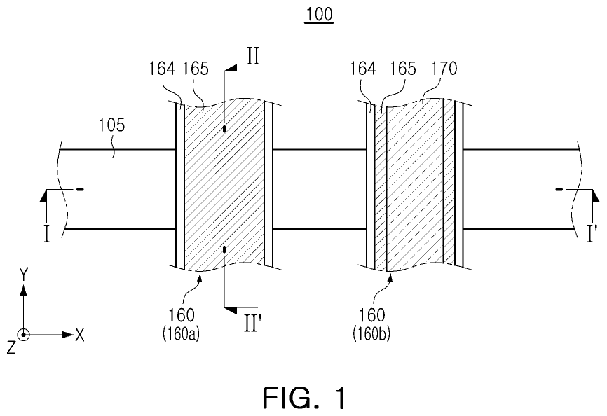

FIG. 1 is a schematic plan view illustrating a semiconductor device according to example embodiments. For convenience of description, FIG. 1 illustrates only some components of the semiconductor device.

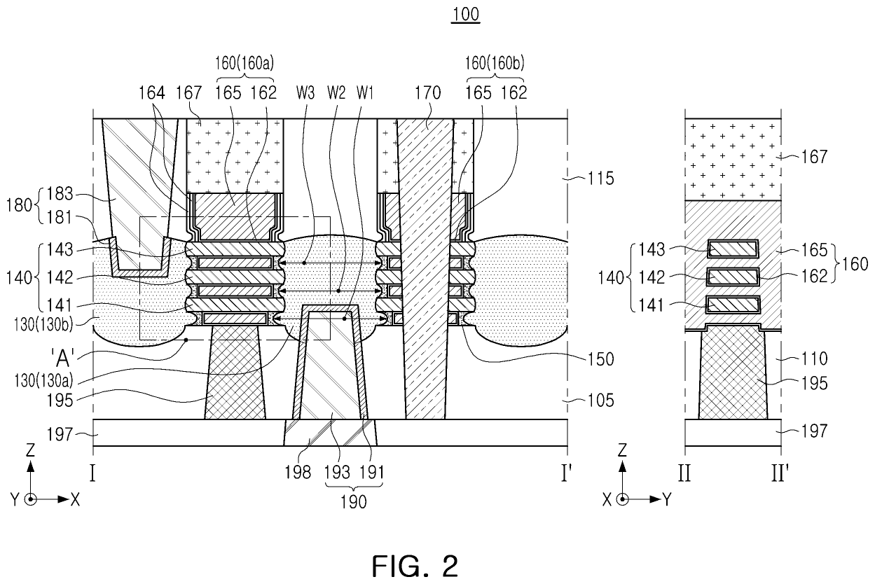

FIG. 2 includes schematic cross-sectional views illustrating a semiconductor device according to example embodiments. FIG. 2 schematically illustrates cross-sections taken along cutting lines I-I′ and II-II′ of the semiconductor device of FIG. 1.

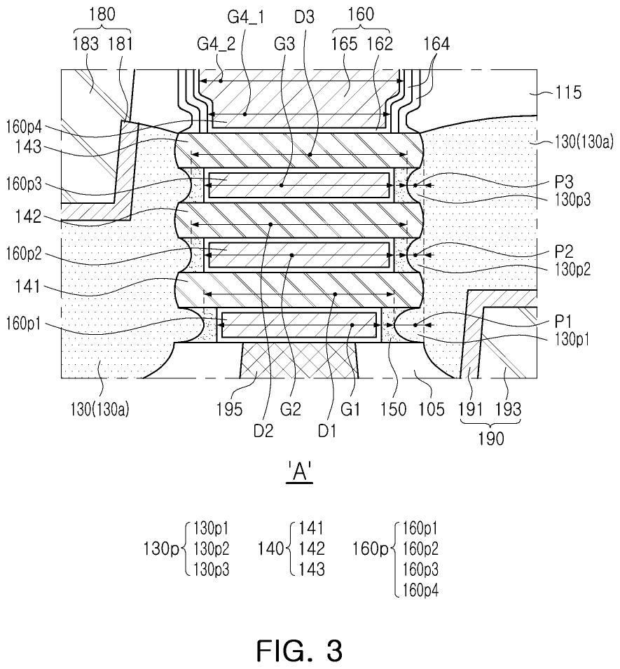

FIG. 3 is a schematic partial enlarged view illustrating a semiconductor device according to example embodiments. FIG. 3 is an enlarged view of region ‘A’ of FIG. 2.

Referring to FIGS. 1 to 3, a semiconductor device 100 may include an active region 105, channel structures 140 including a first channel layer 141, a second channel layer 142, and a third channel layer 143 vertically spaced apart from each other on the active region 105, gate structures 160 extending by intersecting the active region 105 and respectively including a gate electrode 165, source/drain regions 130 connected to the channel structures 140, internal spacers 150 disposed between the gate structure 160 and the source/drain regions 130 below each of the channel layers 141, 142, and 143, a frontside contact plug 180 and a backside contact plug 190 connected to the source/drain regions 130, a lower separation structure 195 penetrating through the active region 105, a lower insulating layer 197 covering a lower surface of the active region 105, and a backside power structure 198 penetrating through the lower insulating layer 197 and connected to the backside contact plug 190. The semiconductor device 100 may further include a device isolating layer 110 and an interlayer insulating layer 115.

In the semiconductor device 100, the active region 105 may have a fin structure, and the gate electrode 165 may be disposed between the active region 105 and the channel structure 140, between the first channel layer 141, the second channel layer 142, and the third channel layer 143 of the channel structure 140, and on the channel structure 140. Accordingly, a semiconductor device 100A may include transistors having a MBCFET™ (Multi Bridge Channel FET) structure, which is a gate-all-around type field effect transistor.

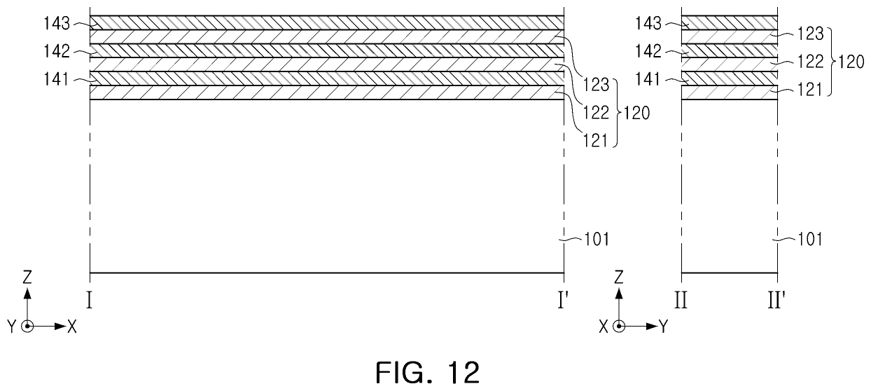

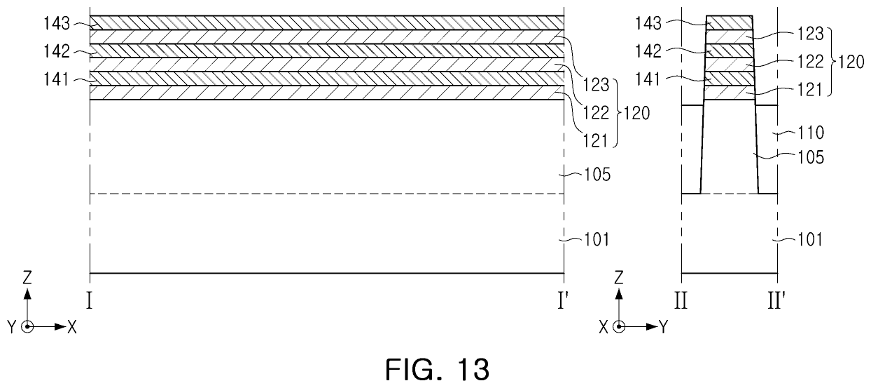

The active region 105 may have an upper surface extending in a first direction (e.g., X-direction). The active region 105 may include a semiconductor material, such as a group IV semiconductor, a group III-V compound semiconductor, or a group II-VI compound semiconductor. For example, the group IV semiconductor may include silicon, germanium, or silicon-germanium. Referring to FIGS. 12 and 13 together, the active region 105 may be a component included in a substrate 101 having an upper surface extending in the X-direction and a Y-direction, and as a manufacturing method progresses, at least a portion of the substrate 101 may be removed, so that an active region 105, a portion of the substrate 101, may remain in the semiconductor device 100. The substrate 101 may be provided as a bulk wafer, an epitaxial layer, a Silicon-On-Insulator (SOI) layer, or a Semiconductor-On-Insulator (SeOI) layer. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The active region 105 may be defined by the device isolating layer 110, and may be disposed to extend in one direction, for example, the X-direction. The X-direction may be defined as a first direction or a second direction. The active region 105 may partially protrude onto the device isolating layer 110, so that an upper surface of the active region 105 may be disposed on a higher level than an upper surface of the device isolating layer 110. On both sides of the gate structure 160, the active region 105 may be partially recessed to form recessed regions, and the source/drain regions 130 may be disposed in the recessed regions.

In example embodiments, the active region 105 may or may not include a well region including impurities. For example, in the case of a P-type transistor (pFET), the well region may include N-type impurities such as phosphorus (P), arsenic (As), or antimony (Sb), and in the case of an N-type transistor (nFET), the well region may include P-type impurities such as boron (B), gallium (Ga), or indium (In). The well region may be disposed, for example, at a predetermined depth from the upper surface of the active region 105.

The device isolating layer 110 may define the active region 105 in the substrate 101. The device isolating layer 110 may be formed, for example, by a shallow trench isolation (STI) process. The device isolating layer 110 may expose the upper surface of the active region 105 and may also expose a portion of the upper surface. In some example embodiments, the device isolating layer 110 may have a curved upper surface so as to have a higher level as the device isolating layer 110 approaches the active region 105. The device isolating layer 110 may be formed of an insulating material. The device isolating layer 110 may be, for example, an oxide, a nitride, or combinations thereof.

The channel structures 140 may be disposed on the active region 105 in regions in which the active region 105 intersects the gate structures 160. Each of the channel structures 140 may include a plurality of channel layers, for example, a first channel layer 141, a second channel layer 142, and a third channel layer 143, which are spaced apart from each other in a Z-direction. The first channel layer 141, the second channel layer 142, and the third channel layer 143 may be disposed sequentially from a lower portion of the gate structure. The first channel layer 141 disposed on the lowest level in the vertical direction (e.g., Z direction) may be referred to as a lowermost channel layer and the third channel layer 143 disposed on the highest level in the vertical direction may be referred to as an uppermost channel layer. The second channel layer 142 may be referred to as an intermediate channel layer. The channel structures 140 may be connected to the source/drain regions 130. The channel structures 140 may have a width that is identical to or similar to the gate structures 160 in the X-direction, and may have a width that is identical to or less than the active region 105 in the Y-direction. In a cross-section in the Y-direction, a channel layer disposed in a lower portion of the gate structure, among the first channel layer 141, the second channel layer 142, and the third channel layer 143, may have a width that is identical to or greater than a channel layer disposed in an upper portion of the gate structure. The number and shape of the channel layers included in one channel structure 140 may be variously changed in example embodiments. For example, one channel structure 140 may include four channel layers, may include two channel layers, or may include five or more channel layers.

The channel structures 140 may be formed of a semiconductor material, for example, at least one of silicon (Si), silicon germanium (SiGe), or germanium (Ge). The channel structures 140 may be formed of, for example, the same material as the active region 105. In some example embodiments, the channel structures 140 may include an impurity region disposed in a region adjacent to the source/drain regions 130.

The gate structures 160 may be disposed on the active region 105 and the channel structures 140 to intersect the active region 105 and the channel structures 140 and may extend in one direction, for example, the Y-direction. The Y-direction may be defined as the second direction or the first direction. When the active region 105 is defined as extending in the first direction, the gate structures 160 may be defined as extending in the second direction, intersecting the first direction. Conversely, the gate structures 160 may be defined as extending in the first direction, and in this case, the active region 105 may be defined as extending in the second direction, intersecting the first direction. A functional channel region of the transistors may be formed in the active region 105 and/or the channel structures 140, intersecting the gate electrodes 165 of the gate structures 160. The first direction and the second direction may be referred to as a first horizontal direction and a second horizontal direction, respectively. In some example embodiments, one of a first gate structure 160a and a second gate structure 160b disposed adjacently may be a component separated by a blocking structure 170. For example, the second gate structure 160b may be separated by the blocking structure 170.

Each of the gate structures 160 may include a first gate portion 160p1 below the first channel layer 141, a second gate portion 160p2 below the second channel layer 142, a third gate portion 160p3 below the third channel layer 143, and a fourth gate portion 160p4 on the third channel layer 143. The first gate portion 160p1 may be disposed between the first channel layer 141 and the active region 105 and may have a first gate width G1. The second gate portion 160p2 may be disposed between the second channel layer 142 and the first channel layer 141 and may have a second gate width G2. The third gate portion 160p3 may be disposed between the third channel layer 143 and the second channel layer 142 and may have a third gate width G3. The fourth gate portion 160p4 may be disposed on the third channel layer 143, and may include a portion having a fourth gate width G4_2 and a portion having a recessed gate width G4_1 less than the fourth gate width G4_2 on a lower level in the Z-direction than that of the portion having the fourth gate width G4_2.

When the gate structures 160 extend, for example, in the Y-direction, the first gate width G1, the second gate width G2, the third gate width G3, and the fourth gate width G4_2 may be widths in the X-direction. The first gate portion 160p1, the second gate portion 160p2, and the third gate portion 160p3 may have widths identical to or different from each other depending on the shape of the source/drain regions 130. The first gate width G1 may be less than each of the second gate width G2 and the third gate width G3. A difference between the second gate width G2 and the third gate width G3 may be less than a difference between the first gate width G1 and the second gate width G2. A difference between the second gate width G2 and the third gate width G3 may be less than a difference between the first gate width G1 and the third gate width G3. In some example embodiments, the second gate width G2 and the third gate width G3 may be substantially the same as each other. A fourth gate portion G4 may include portions having different widths. The fourth gate portion G4 may have a recessed side surface. That is, the gate structure 160 may have a recessed side surface on the third channel layer 143. Since the fourth gate portion G4 has a recessed side surface in a lower portion, the fourth gate portion G4 may include a portion having a recessed gate width G4_1, and a portion having a fourth gate width G4_2 greater than the recessed gate width G4_1 on a level higher in the Z-direction than that of the portion having the recessed gate width G4_1.

Each of the gate structures 160 may include a gate electrode 165 and gate dielectric layers 162. In some embodiments, the gate structures 160 may further include gate spacer layers 164 and gate capping layers 167.In other embodiments, the gate spacer layers 164 and the gate capping layers 167 may be separate components from the gate structure 160.

The gate dielectric layers 162 may be disposed between the active region 105 and the gate electrode 165 and between the channel structure 140 and the gate electrode 165, and may be disposed to cover at least portions of surfaces of the gate electrode 165. For example, the gate dielectric layers 162 may be disposed to surround all surfaces except for an uppermost surface of the gate electrode 165. The gate dielectric layers 162 may be in contact with the internal spacers 150 below the plurality of channel layers 141, 142, and 143, and may be spaced apart from the source/drain regions 130 by the internal spacers 150. The gate dielectric layers 162 may extend between the gate electrode 165 and the gate spacer layers 164, but the present disclosure is not limited thereto. The gate dielectric layers 162 may include oxides, nitrides, or high-κ materials. The high-κ material may mean a dielectric material having a higher dielectric constant than a silicon oxide film (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). According to example embodiments, the gate dielectric layers 162 may be formed of a multilayer film.

The gate electrode 165 may be disposed to fill a gap between the first channel layer 141, the second channel layer 142, and the third channel layer 143 on the active region 105 and extend onto the channel structure 140. The gate electrode 165 may be spaced apart from the first channel layer 141, the second channel layer 142, and the third channel layer 143 by gate dielectric layers 162. The gate electrode 165 may include a conductive material, and may include, for example, a metal nitride such as a titanium nitride (TiN), a tantalum nitride (TaN), or a tungsten nitride (WN); a metallic material such as aluminum (Al), tungsten (W), or molybdenum (Mo); or a semiconductor material such as doped polysilicon. According to example embodiments, the gate electrode 165 may be formed of two or more multilayers.

The gate spacer layers 164 may be disposed on both side surfaces of the gate electrode 165 on the channel structure 140. That is, the gate spacer layers 164 may be disposed on both side surfaces of the fourth gate portion 160p4. The gate spacer layers 164 may insulate the source/drain regions 130 and the gate electrode 165. The gate spacer layers 164 may be formed of a multilayer structure, according to example embodiments. The gate spacer layers 164 may be formed of at least one of an oxide, a nitride, or an oxynitride, and may be formed of, for example, a low-κ film.

The gate capping layer 167 may be disposed on the gate electrode 165 and the gate spacer layers 164. An upper surface of the gate capping layer 167 may be coplanar with an upper surface of the interlayer insulating layer 115. In some example embodiments, a lower surface of the gate capping layer 167 may have a convex shape facing downwardly. The gate capping layer 167 may include an insulating material, for example, at least one of an oxide, a nitride, or an oxynitride.

The source/drain regions 130 may be disposed in recessed regions that partially recess an upper portion of the active region 105 on both sides of the gate structure 160. The recessed regions may extend along side surfaces of the channel structures 140 and side surfaces of the gate dielectric layers 162. The source/drain regions 130 on both sides of the gate structure 160 may be spaced apart from each other in the first direction (e.g., the X-direction), which may be referred to as first source/drain region 130a and second source/drain region 130b, respectively. The source/drain regions 130 may be disposed to cover side surfaces of each of the first channel layer 141, the second channel layer 142, and the third channel layer 143 of the channel structures 140 in the X-direction. Upper surfaces of the source/drain regions 130 may be disposed on a level in the Z-direction identical to or higher than that of lower surfaces of the gate electrodes 165 on the channel structures 140, and the level may be variously changed in example embodiments. Side surfaces of the source/drain regions 130 may have bent portions according to the first channel layer 141, the second channel layer 142, and the third channel layer 143 and the internal spacers 150. The side surfaces of the source/drain regions 130 may be in a form protruding toward the gate structure 160 between the plurality of channel layers 141, 142, and 143.

Each of the source/drain regions 130 may include a plurality of protrusion portions 130p including a first protrusion portion 130p1, a second protrusion portion 130p2, and a third protrusion portion 130p3 protruding toward the gate structure 160 below each of the plurality of channel layers 141, 142, and 143. At least one of the plurality of protrusion portions 130p may include a portion overlapping the gate structure 160 in a vertical direction (e.g., in the Z-direction). The first protrusion portion 130p1, the second protrusion portion 130p2, and the third protrusion portion 130p3 may be substantially the same as each other, or may be formed to have a different shape, depending on the concentration of sacrificial layers 120 (see FIG. 12) stacked in corresponding positions. The first protrusion portion 130p1 may be disposed between the first channel layer 141 and the active region 105, i.e., on the same level in the Z-direction as the first gate portion 160p1. The second protrusion portion 130p2 may be disposed between the second channel layer 142 and the first channel layer 141, i.e., on the same level in the Z-direction as the second gate portion 160p2. The third protrusion portion 130p3 may be disposed between the third channel layer 143 and the second channel layer 142, i.e., on the same level in the Z-direction as the third gate portion 160p3. The first protrusion portion 130p1 may be referred to as a lowermost protrusion portion, and the third protrusion portion 130p3 may be referred to as an uppermost protrusion portion. In some example embodiments, when one channel structure 140 includes four channel layers, a fourth protrusion portion may be referred to as an uppermost protrusion portion.

The first protrusion portion 130p1 may have a first protrusion length P1, the second protrusion portion 130p2 may have a second protrusion length P2, and the third protrusion portion 130p3 may have a third protrusion length P3. The first protrusion length P1, the second protrusion length P2, and the third protrusion length P3 may be substantially the same value as each other, or may have different values. The first protrusion length P1 may be greater than each of the second protrusion length P2 and the third protrusion length P3. In some example embodiments, the second protrusion length P2 and the third protrusion length P3 may be substantially equal to each other.

Since the source/drain region 130 includes the first protrusion portion 130p1, the second protrusion portion 130p2, and the third protrusion portion 130p3, the source/drain region 130 may have different widths in the first horizontal direction (e.g., X-direction) depending on the level in the Z-direction. A level portion including the first protrusion portion 130p1 may have a first width W1, a level portion including the second protrusion portion 130p2 may have a second width W2, and a level portion including the third protrusion portion 130p3 may have a third width W3. The first width W1, the second width W2, and the third width W3 may be maximum widths of each level portion. The first width W1 may be greater than each of the second width W2 and the third width W3. In some example embodiments, the second width W2 and the third width W3 may be substantially equal to each other. In some example embodiments, the difference between the second width W2 and the third width W3 may be less than the difference between the first width W1 and the second width W2. In some example embodiments, a difference between the second width W2 and the third width W3 may be less than a difference between the first width W1 and the third width W3. The first width W1, the second width W2, and the third width W3 may have different values depending on the shapes of the first protrusion portion 130p1, the second protrusion portion 130p2, and the third protrusion portion 130p3, respectively.

Depending on the first protrusion length P1, the second protrusion length P2, and the third protrusion length P3, a separation distance between the first source/drain region 130a and the second source/drain region 130b disposed on both sides of the gate structure 160 may be variously changed depending on the level. A distance at which the first protrusion portions 130p1 of each of the first source/drain region 130a and the second source/drain region 130b are spaced apart from each other may be a first distance D1, a distance at which the second protrusion portions 130p2 are spaced apart from each other may be a second distance D2, and a distance at which the third protrusion portions 130p3 are spaced apart from each other may be a third distance D3. When internal spacers 150 are disposed between the first protrusion portion 130p1, the second protrusion portion 130p2, and the third protrusion portion 130p3 and each of the first gate portion 160p1, the second gate portion 160p2, and the third gate portion 160p3, respectively, each of the first distance D1, the second distance D2, and the third distance D3 may be greater than each of the first gate width G1, the second gate width G2, and the third gate width G3, respectively. In some example embodiments, when the internal spacers 150 are not present, the first distance D1, the second distance D2, and the third distance D3 may be equal to the first gate width G1, the second gate width G2, and the third gate width G3, respectively. The first distance D1 may be less than the second distance D2 and the third distance D3. In some example embodiments, the second distance D2 and the third distance D3 may be substantially equal to each other. The first distance D1 may be the shortest distance between adjacent source/drain regions 130, for example, the first source/drain region 130a and the second source/drain region 130b.

A specific shape of the side surfaces of the source/drain regions 130 may be variously changed in example embodiments. The source/drain regions 130 may be epitaxially grown regions, and may include multiple epitaxial layers. An epitaxially grown surface of the source/drain regions 130 may be in contact with the channel structures 140, the internal spacers 150, and the interlayer insulating layer 115.

The source/drain regions 130 may include a semiconductor material, for example, at least one of silicon (Si) or germanium (Ge), and may further include dopants. For example, when the semiconductor device 100A is an nFET, the dopants may be at least one of phosphorus (P), arsenic (As), or antimony (Sb). For example, when the semiconductor device 100A is a pFET, the dopants may be at least one of boron (B), gallium (Ga), or indium (In). According to an example embodiment, the source/drain regions 130 may be formed of a plurality of epitaxial layers.

Some embodiments may include source/drain regions 130 including lowermost protrusion portions 130p1 having relatively large protrusion lengths, and thus, the first distance D1 between the lowermost protrusion portions 130p1 may be formed to be relatively small. By the shape of these source/drain regions 130, the first gate width G1 of the first gate portion 160p1 may be formed to be less than the second gate width G2 of the second gate portion 160p2 and the third gate width G3 of the third gate portion 160p3. By forming a protrusion length of the lowermost protrusion portion 130p1 to be relatively longer, an area in which the lowermost protrusion portion 130p1 overlaps the gate structure 160 may increase, and a space of the backside contact plug 190, especially a back metal-semiconductor compound layer 191, may be sufficiently secured. The second gate width G2 and the third gate width G3 may be formed to be relatively large, thus improving electrical characteristics of the corresponding portions. The source/drain regions 130 and the gate structures 160 may be included, thereby providing a semiconductor device having improved reliability and electrical characteristics. The effect of the present disclosure related to the manufacturing method are described below in the description related thereto.

The interlayer insulating layer 115 may be disposed on the device isolating layer 110 to cover the upper surface of the device isolating layer 110 and the source/drain region 130. The lower insulating layer 197 may cover the lower surface of the active region 105, a lower surface of the blocking structure 170, and a lower surface of the lower separation structure 195. The interlayer insulating layer 115 and the lower insulating layer 197 may include at least one of an oxide, a nitride, or an oxynitride, and may include, for example, a low-κ material. According to example embodiments, at least one of the interlayer insulating layer 115 and the lower insulating layer 197 may include a plurality of insulating layers.

The internal spacers 150 may be disposed between the gate structure 160 and the source/drain region 130, below each of the plurality of channel layers 141, 142, and 143 on the active region 105. The internal spacers 150 may be disposed in parallel with the gate electrode 165 between the first channel layer 141, the second channel layer 142, and the third channel layer 143 in the third direction (e.g., the Z-direction). The internal spacers 150 may cover side surfaces of the gate structure 160 below the channel structure 140 in the X-direction. The gate structure 160 and the source/drain region 130 may be spaced apart from each other by the internal spacers 150 below each of the first channel layer 141, the second channel layer 142, and the third channel layer 143. The internal spacers 150 may include an insulating material, for example, at least one of an oxide, a nitride, or an oxynitride.

The blocking structure 170 may extend in a second direction, for example, in the Y-direction, by intersecting the active region 105. The blocking structure 170 may be disposed between adjacent source/drain regions 130. An upper surface of the blocking structure 170 may be disposed on a higher level in the Z-direction than that of an upper surface of the gate electrode 165, and may be substantially coplanar with the upper surface of the gate capping layer 167 and the upper surface of the interlayer insulating layer 115. A lower surface of the blocking structure 170 may be substantially coplanar with a lower surface of the active region 105. The blocking structure 170 may penetrate through and separate one of the gate structures 160, for example, the second gate structure 160b. The blocking structure 170 may penetrate and separate the active region 105. The blocking structure 170 may electrically separate adjacent transistors. The blocking structure 170 may include an insulating material, and may include at least one of an oxide, a nitride, or an oxynitride. In some example embodiments, the blocking structure 170 may include a low-κ material. However, in some example embodiments, the blocking structure 170 may not be present.

The contact plugs 180 and 190 may be connected to the source/drain regions 130 and may apply an electrical signal to the source/drain regions 130. The contact plugs 180 and 190 may recess the source/drain regions 130 and may extend into the source/drain regions 130. The contact plugs 180 and 190 may include a frontside contact plug 180 penetrating the interlayer insulating layer 115 and disposed by recessing the source/drain region 130 from an upper portion, and a backside contact plug 190 penetrating the active region 105 and disposed by recessing the source/drain region 130 from a lower portion.

The frontside contact plug 180 may have a side surface inclined toward the active region 105 due to the aspect ratio, that is, to reduce a width if the frontside contact plug 180 as a level in the Z-direction of the frontside contact plug 180 decreases, but the present disclosure is not limited thereto. The frontside contact plug 180 may extend below a lower surface of the third channel layer 143 from an upper portion of the channel structure 140 and may extend below a lower surface of the second channel layer 142, according to an embodiment. For example, a lower end of the frontside contact plug 180 may be disposed on a lower level in the Z-direction than that of the third protrusion portion 130p3.

The frontside contact plug 180 may include a front metal-semiconductor compound layer 181 and a front contact conductive layer 183. The front metal-semiconductor compound layer 181 may be in contact with the source/drain region 130. The front metal-semiconductor compound layer 181 may be disposed along a recessed surface of the source/drain region 130. An upper end of the front metal-semiconductor compound layer 181 may be disposed on a level in the Z-direction identical to or higher than that of an upper surface of the third channel layer 143. An upper end of the front metal-semiconductor compound layer 181 may be disposed on a level in the Z-direction identical to or higher than that of an upper surface of the source/drain region 130. A lower end of the front metal-semiconductor compound layer 181 may be disposed on a level in the Z-direction lower than that of the third protrusion portion 130p3, i.e., an uppermost protrusion portion 130p3. The front metal-semiconductor compound layer 181 may include a metal element and a semiconductor element, and may include, for example, at least one of TiSi, CoSi, MoSi, LaSi, NiSi, TaSi, or WSi. Alternatively, the front metal-semiconductor compound layer 181 may include germanium (Ge) in addition to silicon (Si) into the materials or instead of silicon (Si). The front contact conductive layer 183 may be disposed on the front metal-semiconductor compound layer 181. The front contact conductive layer 183 may include a metallic material such as, for example, tungsten (W), cobalt (Co), molybdenum (Mo), copper (Cu), ruthenium (Ru), or aluminum (Al).

The backside contact plug 190 may have an inclined side surface so that a width the backside contact plug 190 decreases as a level in the Z-direction of the backside contact plug 190 increases due to the aspect ratio, but the present disclosure is not limited thereto. The backside contact plug 190 may extend above a lower surface of the first channel layer 141 from a lower portion of the channel structure 140 and may extend above the lower surface of the second channel layer 142, according to an example embodiment. For example, an upper surface of the backside contact plug 190 may be disposed on a level in the Z-direction higher than that of the first protrusion portion 130p1. A lower surface of the backside contact plug 190 may be coplanar with lower surfaces of the active region 105, the blocking structure 170, and the lower separation structure 195.

The backside contact plug 190 may include a back metal-semiconductor compound layer 191 and a back contact conductive layer 193. The back metal-semiconductor compound layer 191 may be in contact with the source/drain region 130 and the active region 105. The back metal-semiconductor compound layer 191 may be disposed along a surface on which the source/drain region 130 and the active region 105 are recessed. A lower end of the back metal-semiconductor compound layer 191 may be disposed on the same level in the Z-direction as the lower surface of the active region 105. The lower end of the back metal-semiconductor compound layer 191 may be disposed on the same level in the Z-direction as the lower surface of the lower separation structure 195 and the lower surface of the blocking structure 170. An upper end of the back metal-semiconductor compound layer 191 may be disposed on a level in the Z-direction higher than that of the first protrusion portion 130p1. The back metal-semiconductor compound layer 191 may include a metal element and a semiconductor element, and may include, for example, at least one of TiSi, CoSi, MoSi, LaSi, NiSi, TaSi, or WSi. Alternatively, the back metal-semiconductor compound layer 191 may include germanium (Ge) in addition to silicon (Si) into the materials or instead of silicon (Si). The back contact conductive layer 193 may be disposed below the back metal-semiconductor compound layer 191. The back contact conductive layer 193 may include, for example, a metallic material such as tungsten (W), cobalt (Co), molybdenum (Mo), copper (Cu), ruthenium (Ru), or aluminum (Al).

Gate contact plugs and interconnection structures such as contact plugs 180 and 190 may be further disposed on the gate electrode 165, and an interconnection structure such as an interconnection line connected to the frontside contact plug 180 may be further disposed on the frontside contact plug 180.

The lower separation structure 195 may be disposed below a lowermost surface of the gate structures 160. The lower separation structure 195 may penetrate through the active region 105 and may be in contact with each of the gate structures 160, and may separate the active region 105. By the lower separation structure 195, leakage current that may occur in the active region 105 below the gate structures 160 may be prevented. The lower separation structure 195 may have a shape in which a width of the lower separation structure 195 decreases as a level in the Z-direction of the lower separation structure 195 increases, but the present disclosure is not limited thereto. For example, in some example embodiments, the lower separation structure 195 may have a shape in which, as a level in the Z-direction of the lower separation structure 195 increases, a width of the lower separation structure 195 increases and then decreases again. In the second direction (e.g., the Y-direction), widths of each of the lower separation structures 195 may be equal to or greater than a width of the active region 105. The active region 105 extending in the first direction (e.g., the X-direction) may be separated by the lower separation structure 195. The lower separation structure 195 may include an insulating material, and include, for example, at least one of an oxide, a nitride, or an oxynitride.

The backside power structure 198 may be connected to a lower end or a lower surface of the backside contact plug 190. The backside power structure 198 may penetrate through the lower insulating layer 197 and may be connected to the backside contact plug 190. The backside power structure 198 may form a BSPDN applying power or a ground voltage, together with the backside contact plug 190, and may also be referred to as a backside power rail or a buried power rail. In some example embodiments, the backside power structure 198 may be a buried interconnection line extending, for example, in the Y-direction, below the backside contact plug 190, but the present disclosure is not limited thereto. For example, in some example embodiments, the backside power structure 198 may include a via region and/or a line region. In some example embodiments, the backside power structure 198 may be a buried interconnection line extending in the X-direction. A width of the backside power structure 198 may increase continuously as the backside power structure 198 moves downwardly in the Z-direction, but the present disclosure is not limited thereto. The backside power structure 198 may include a conductive material, for example, at least one of tungsten (W), copper (Cu), aluminum (Al), cobalt (Co), ruthenium (Ru), titanium (Ti), or molybdenum (Mo).

The semiconductor device 100 may be packaged by flipping the structure of FIG. 2 upside down so that the backside power structure 198 is disposed in an upper portion of the semiconductor device 100, but a packaging form of the semiconductor device 100 is not limited thereto.

In the description of example embodiments below, any description overlapping the description described above with reference to FIGS. 1 to 3 will be omitted.

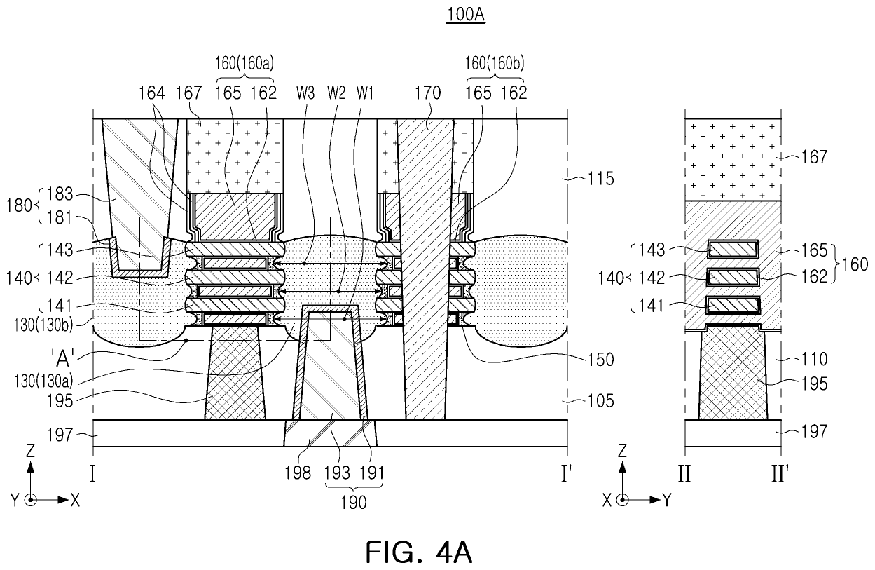

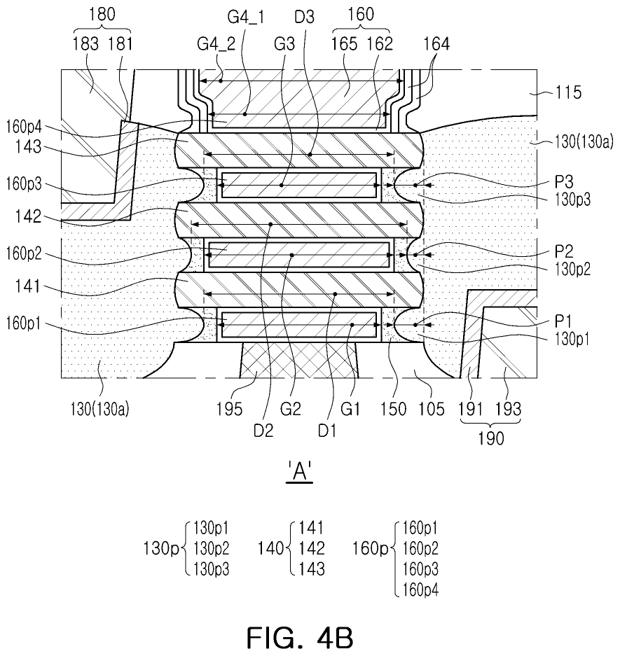

FIG. 4A includes schematic cross-sectional views illustrating a semiconductor device according to example embodiments. FIG. 4A illustrates regions corresponding to FIG. 2.

FIG. 4B is a schematic partial enlarged view illustrating a semiconductor device according to example embodiments. FIG. 4B illustrates an enlarged view of region ‘A’ of FIG. 4A.

Referring to FIGS. 4A and 4B, in the semiconductor device 100A, a third protrusion length P3 of a third protrusion portion 130p3 of a source/drain region 130 may be substantially equal to a first protrusion length P1 of a first protrusion portion 130p1, unlike the semiconductor device 100 of FIGS. 1 to 3. A second protrusion length P2 of a second protrusion portion 130p2 may be less than each of the first protrusion length P1 and the third protrusion length P3. A difference between the first protrusion length P1 and the third protrusion length P3 may be less than a difference between the first protrusion length P1 and the second protrusion length P2. A difference between the first protrusion length P1 and the third protrusion length P3 may be less than a difference between the second protrusion length P2 and the third protrusion length P3. A first width W1 and a third width W3 may be substantially the same as each other. A second width W2 may be less than each of the first width W1 and the third width W3. A difference between the first width W1 and the third width W3 may be less than a difference between the first width W1 and the second width W2. A difference between the first width W1 and the third width W3 may be less than a difference between the second width W2 and the third width W3. Accordingly, a first separation distance D1 and a third separation distance D3 may be substantially the same. A second separation distance D2 may be less than each of the first separation distance D1 and the third separation distance D3. A third gate width G3 of the third gate portion 160p3 may be substantially identical to a first gate width G1 of the first gate portion 160p1. A second gate width G2 of the second gate portion 160p2 may be greater than each of the first gate width G1 and the third gate width G3. The third protrusion length P3 and the first protrusion length P1 may be formed to be relatively longer, thereby allowing sufficient space for the front metal-semiconductor compound layer 181 of the frontside contact plug 180. Additionally, since the gate structure 160 has a recessed side surface in the fourth gate portion 160p4 on an uppermost channel layer 143, so that a separation distance between the fourth gate portion 160p4 and the third protrusion portion 130p3 may be increased to improve a Gate Induced Drain Leakage (GIDL) phenomenon. Unlike the semiconductor device 100 of FIGS. 1 to 3, in the case in which the third protrusion length P3 of the third protrusion portion 130p3 is formed to be relatively long, as in the semiconductor device 100A of FIGS. 4A and 4B, the GIDL phenomenon may be improved by forming the gate spacer layers 164 to be relatively thick, or forming a difference between the recessed gate width G4_1 and the fourth gate width G4_2 to be relatively large. The structural features of example embodiments of the present specification including the semiconductor device 100A may be due to the features of the manufacturing method, and the related contents are described later in the description referring to the manufacturing method.

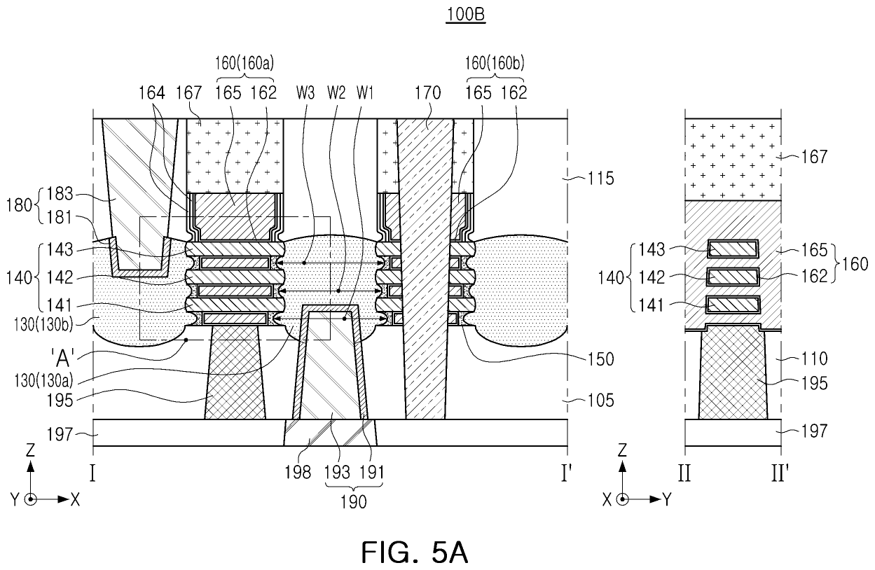

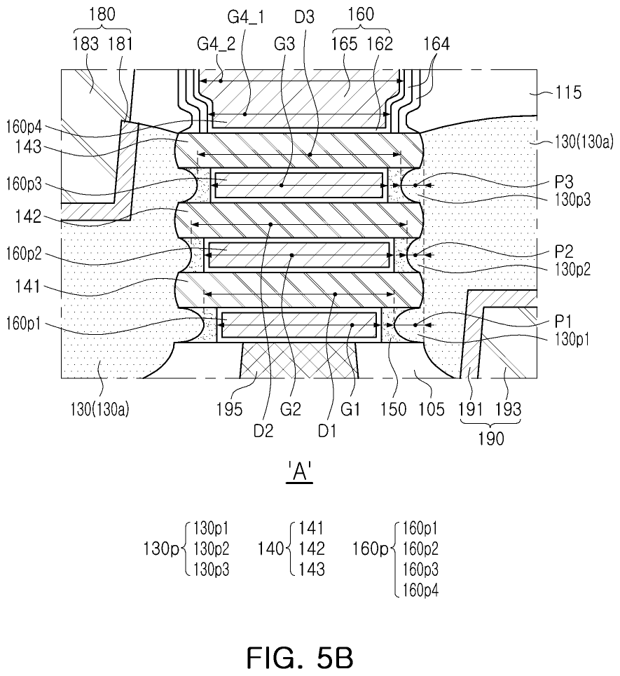

FIG. 5A includes schematic cross-sectional views illustrating a semiconductor device according to example embodiments. FIG. 5A illustrates regions corresponding to FIG. 2.

FIG. 5B is a schematic partial enlarged view illustrating a semiconductor device according to example embodiments. FIG. 5B illustrates an enlarged view of region ‘A’ of FIG. 5A.

Referring to FIGS. 5A and 5B, unlike the semiconductor device 100 of FIG. 2, in a semiconductor device 100B, a first protrusion length P1 of a first protrusion portion 130p1 of a source/drain region 130 may be greater than a third protrusion length P3 of a third protrusion portion 130p3, and the third protrusion length P3 may be greater than a second protrusion length P2 of a second protrusion portion 130p2. For example, when the first protrusion length P1, the second protrusion length P2, and the third protrusion length P3 are arranged in an ascending order, the first protrusion length P1, the third protrusion length P3, and the second protrusion length P2 may be arranged. When the first width W1, the second width W2, and the third width W3 are arranged in an ascending order, the first width W1, the third width W3, and the second width W2 may be arranged. When the first separation distance D1, the second separation distance D2, and the third separation distance D3 are arranged in a decreasing order, the first separation distance D1, the third separation distance D3, and the second separation distance D2 may be arranged. When the first gate width G1, the second gate width G2, and the third gate width G3 are arranged in a decreasing order, the first gate width G1, the third gate width G3, and the second gate width G2 may be arranged.

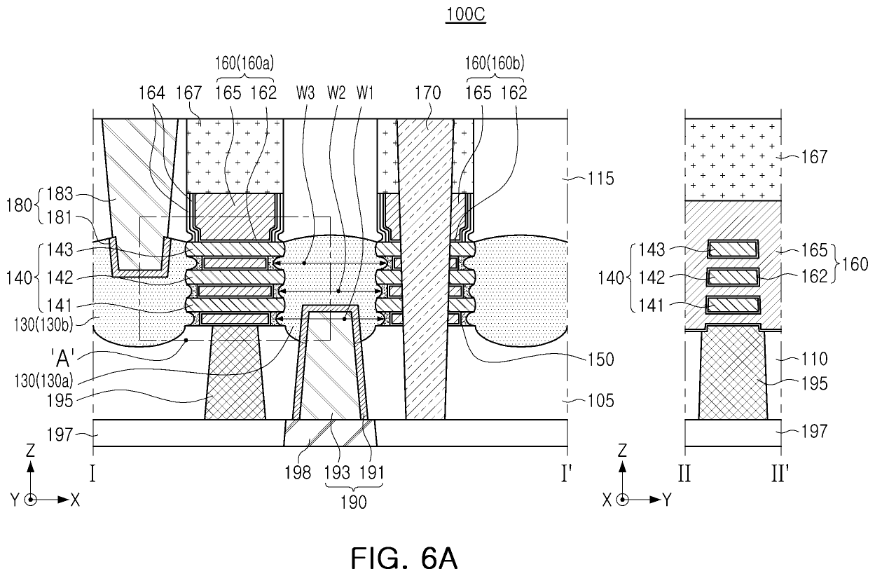

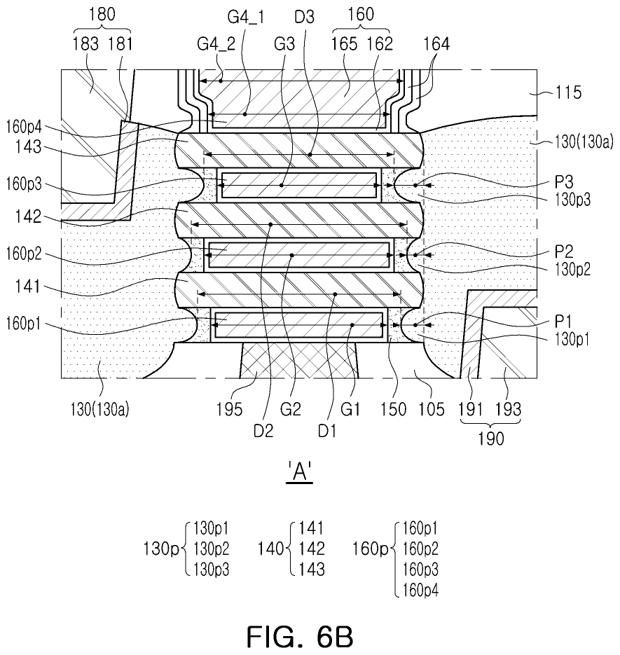

FIG. 6A includes schematic cross-sectional views illustrating a semiconductor device according to example embodiments. FIG. 6A illustrates regions corresponding to FIG. 2.

FIG. 6B is a schematic partial enlarged view illustrating a semiconductor device according to example embodiments. FIG. 6B is an enlarged view illustrating region ‘A’ of FIG. 6A.

Referring to FIGS. 6A and 6B, unlike the semiconductor device 100 of FIG. 2, in a semiconductor device 100C, a third protrusion length P3 of a third protrusion portion 130p3 of a source/drain region 130 may be greater than a first protrusion length P1 of a first protrusion portion 130p1, and the first protrusion length P1 may be greater than a second protrusion length P2 of a second protrusion portion 130p2. For example, when the first protrusion length P1, the second protrusion length P2, and the third protrusion length P3 are arranged in an ascending order, the third protrusion length P3, the first protrusion length P1, and the second protrusion length P2 may be arranged. When the first width W1, the second width W2, and the third width W3 are arranged in an ascending order, the third width W3, the first width W1, and the second width W2 may be arranged. When the first separation distance D1, the second separation distance D2, and the third separation distance D3 are arranged in a decreasing order, the third separation distance D3, the first separation distance D1, and the second separation distance D2 may be arranged. When the first gate width G1, the second gate width G2, and the third gate width G3 are arranged in a decreasing order, the third gate width G3, the first gate width G1, and the second gate width G2 may be arranged.

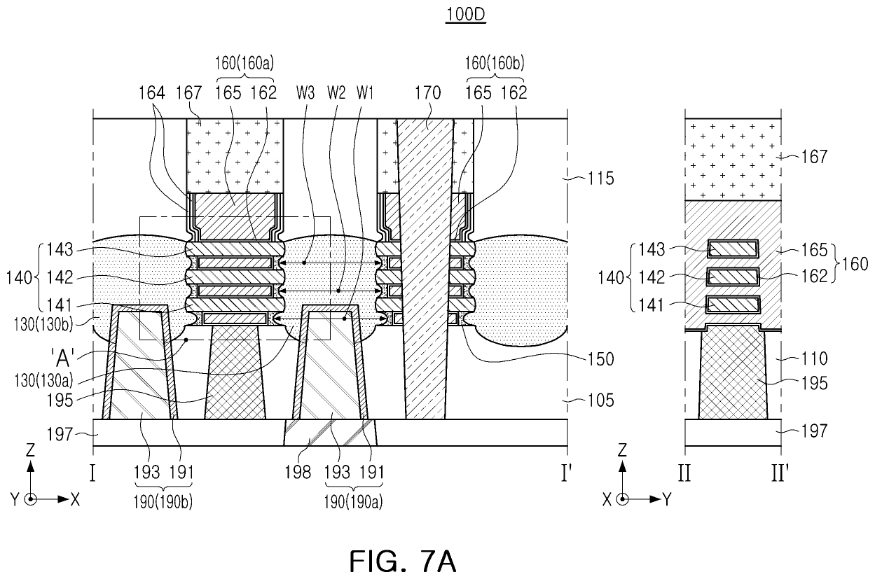

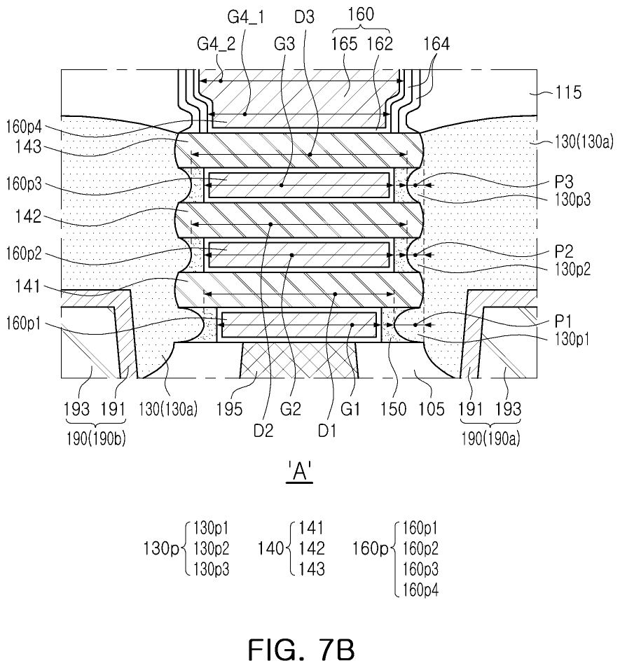

FIG. 7A includes schematic cross-sectional views illustrating a semiconductor device according to example embodiments. FIG. 7A illustrates regions corresponding to FIG. 2.

FIG. 7B is a schematic partial enlarged view illustrating a semiconductor device according to example embodiments. FIG. 7B is an enlarged view illustrating region ‘A’ of FIG. 7A.

Referring to FIGS. 7A and 7B, unlike the semiconductor devices 100 of FIGS. 1 to 3, in a semiconductor device 100D, each of the first source/drain region 130a and the second source/drain region 130b on opposite sides of the gate structure 160 of may be connected to a backside contact plug 190. Since the first protrusion length P1 of the first protrusion portion 130p1 of each of the first source/drain region 130a and the second source/drain region 130b is formed to be relatively long, a space for the back metal-semiconductor compound layer 191 of the backside contact plug 190 may be secured, and the back metal-semiconductor compound layer 191 of the backside contact plug 190 may be stably separated from the first gate portion 160p1.

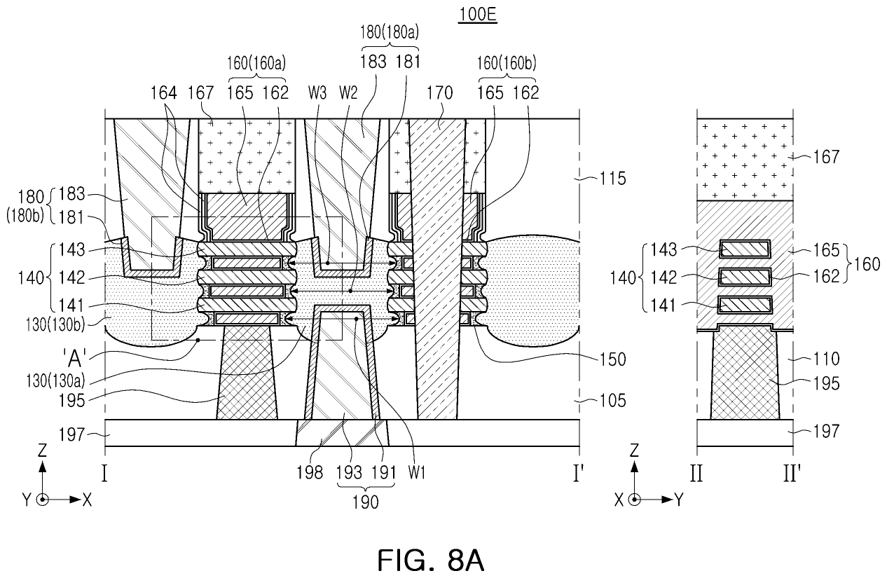

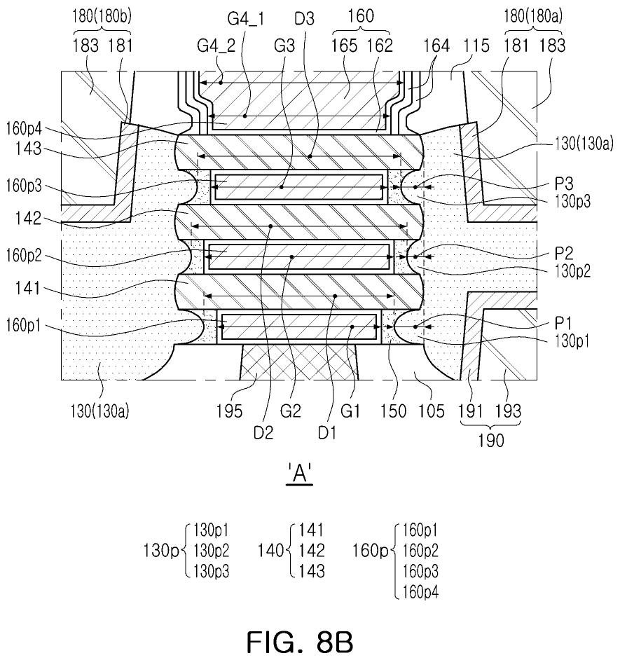

FIG. 8A includes schematic cross-sectional views illustrating a semiconductor device according to example embodiments. FIG. 8A illustrates regions corresponding to FIG. 2.

FIG. 8B is a schematic partial enlarged view illustrating a semiconductor device according to example embodiments. FIG. 8B is an enlarged view illustrating region ‘A’ of FIG. 8A.

Referring to FIGS. 8A and 8B, unlike the semiconductor device 100 of FIGS. 1 to 3, in a semiconductor device 100E, a first source/drain region 130a may be connected to a first frontside contact plug 180a and a backside contact plug 190. The first frontside contact plug 180a may be disposed to penetrate through the interlayer insulating layer 115 and partially recess the first source/drain region 130a from an upper surface thereof. The backside contact plug 190 may be disposed to penetrate through the active region 105 and partially recess the first source/drain region 130a from a lower surface thereof. In some embodiments, the first frontside contact plug 180a and the backside contact plug 190 may overlap each other in the vertical direction (e.g., in the Z-direction). In some embodiments, the first frontside contact plug 180a and the backside contact plug 190 may be spaced apart from each other with the first source/drain region 130a interposed therebetween.

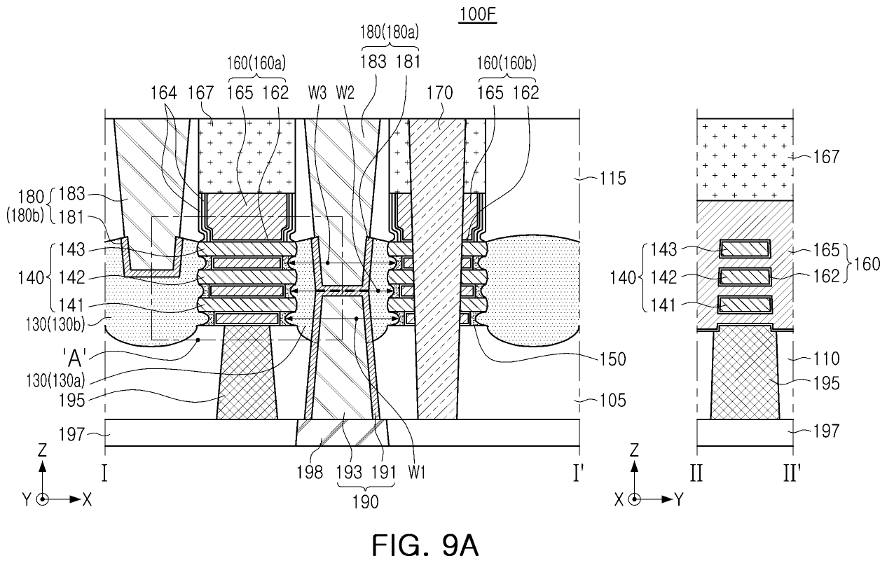

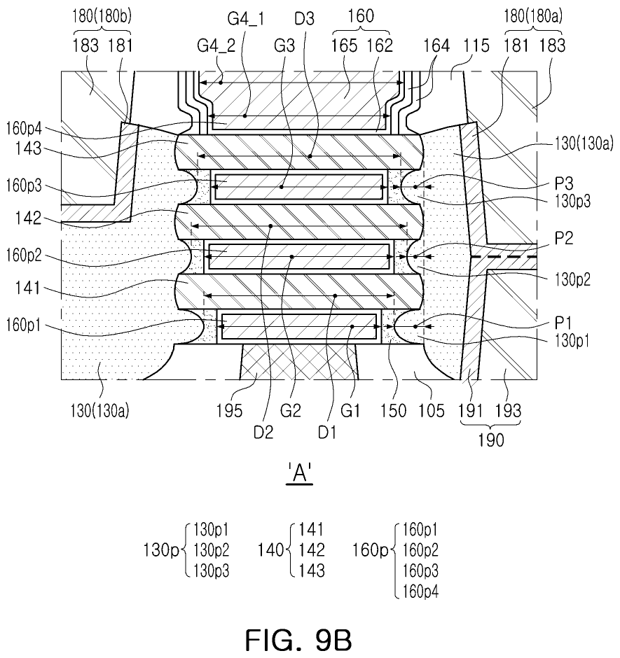

FIG. 9A includes schematic cross-sectional views illustrating a semiconductor device according to example embodiments. FIG. 9A illustrates regions corresponding to FIG. 2.

FIG. 9B is a schematic partial enlarged view illustrating a semiconductor device according to example embodiments. FIG. 9B is an enlarged view illustrating region ‘A’ of FIG. 9A.

Referring to FIGS. 9A and 9B, unlike the semiconductor device 100E of FIGS. 8A and 8B, in a semiconductor device 100F, a first frontside contact plug 180a and the backside contact plug 190 may be in contact with each other in the first source/drain region 130a. The front metal-semiconductor compound layer 181 of the first frontside contact plug 180a and the back metal-semiconductor compound layer 191 of the backside contact plug 190 may be in contact with each other and may merge with each other.

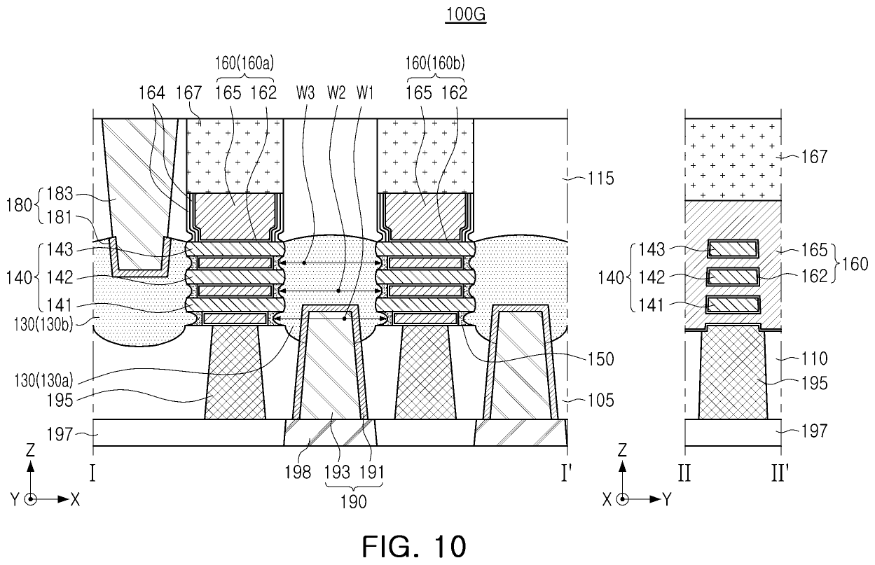

FIG. 10 includes schematic cross-sectional views illustrating a semiconductor device according to example embodiments. FIG. 10 illustrates regions corresponding to FIG. 2.

Referring to FIG. 10, unlike the semiconductor device 100 of FIGS. 1 to 3, in a semiconductor device 100G, a portion of the gate structure 160 may not be separated by a blocking structure 170, and source/drain regions 130 on opposite sides of a first gate structure 160a and a second gate structure 160b may be electrically connected to each other. Some of the source/drain regions 130 may be in contact with and connected to the backside contact plug 190, and other source/drain regions 130 may be in contact with and connected to the frontside contact plug 180. The presence or absence of the blocking structure 170, whether each of the source/drain regions 130 is connected to the frontside contact plug 180 or the backside contact plug 190, or the like, may be variously modified.

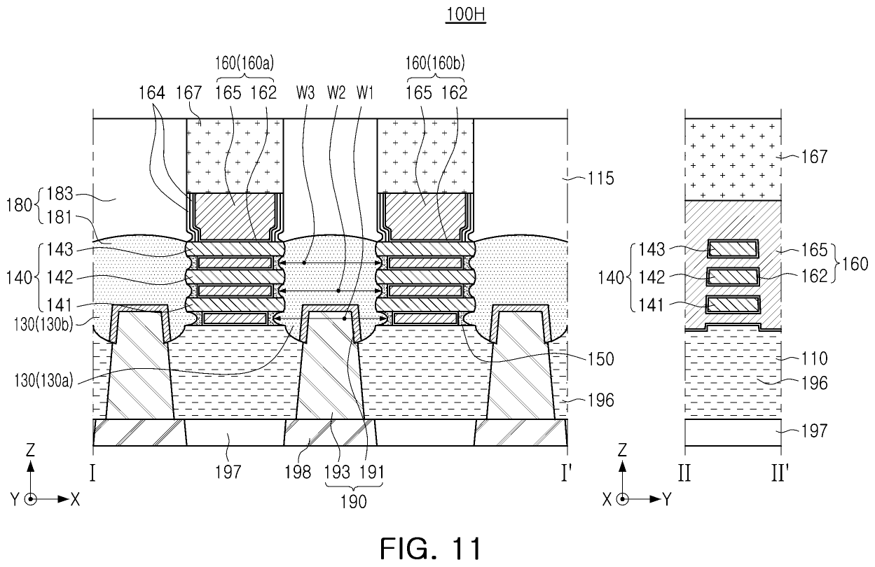

FIG. 11 includes schematic cross-sectional views illustrating a semiconductor device according to example embodiments. FIG. 11 illustrates regions corresponding to FIG. 2.

Referring to FIG. 11, unlike the semiconductor device 100 of FIGS. 1 to 3, in a semiconductor device 100H, an active region 105 may be removed and a substrate insulating layer 196 may be disposed therein. The substrate insulating layer 196 may be disposed by replacing at least a portion of each of the active region 105 and the device isolating layer 110. Unlike the semiconductor device 100 of FIGS. 1 to 3, the lower separation structure 195 may not be present. The back metal-semiconductor compound layer 191 of the backside contact plug 190 may be disposed along a recessed surface of the source/drain region 130, and may not be disposed between the back contact conductive layer 193 and the substrate insulating layer 196.

FIGS. 12, 13, 14, 15A, 16A, 17, 18, 19, 20A, 21A, 22, 23, 24, 25, 26, 27, and 28 are cross-sectional views illustrating a method of manufacturing a semiconductor device according to example embodiments according to a process order. FIGS. 12, 13, 14, 15A, 16A, 17, 18, 19, 20A, 21A, 22, 23, 24, 25, 26, 27, and 28 illustrate regions corresponding to FIG. 2.

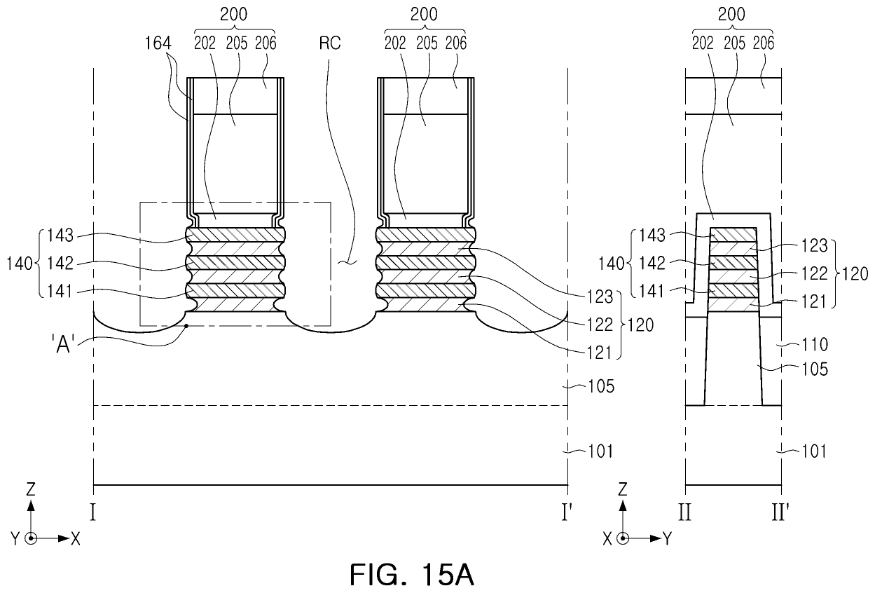

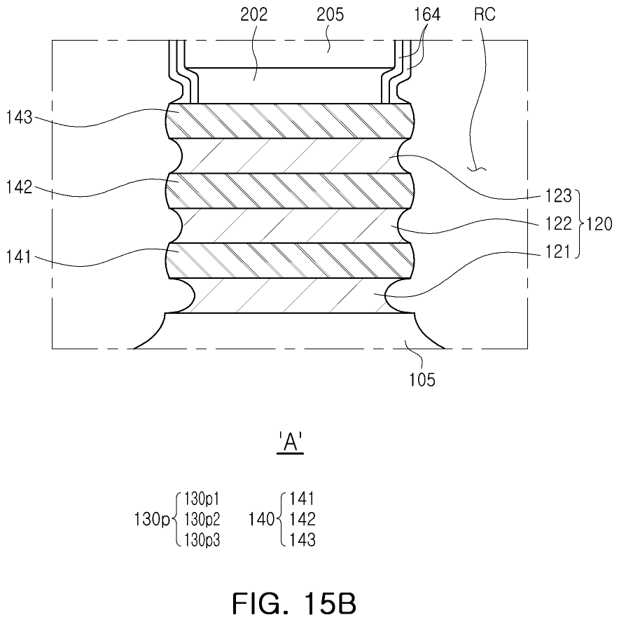

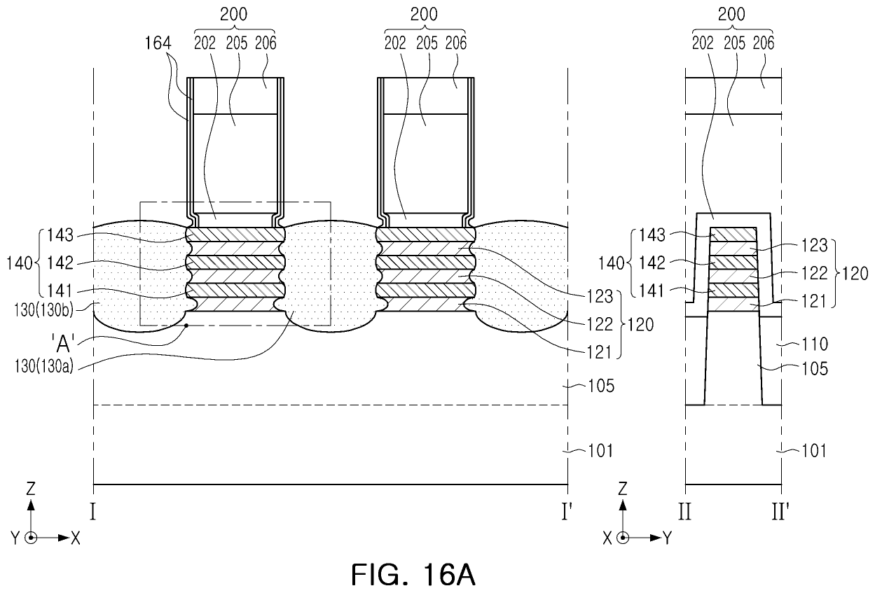

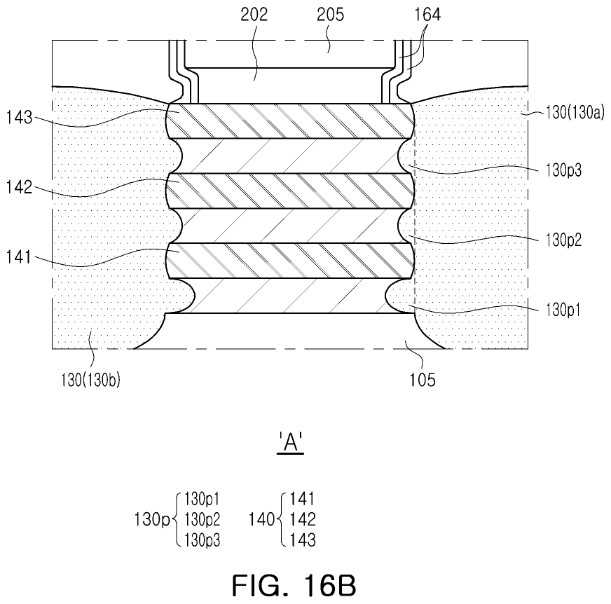

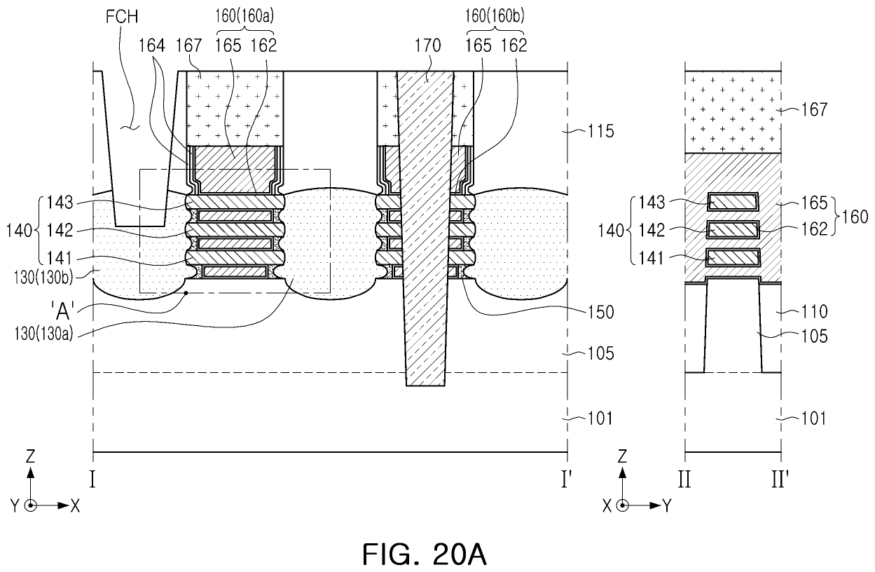

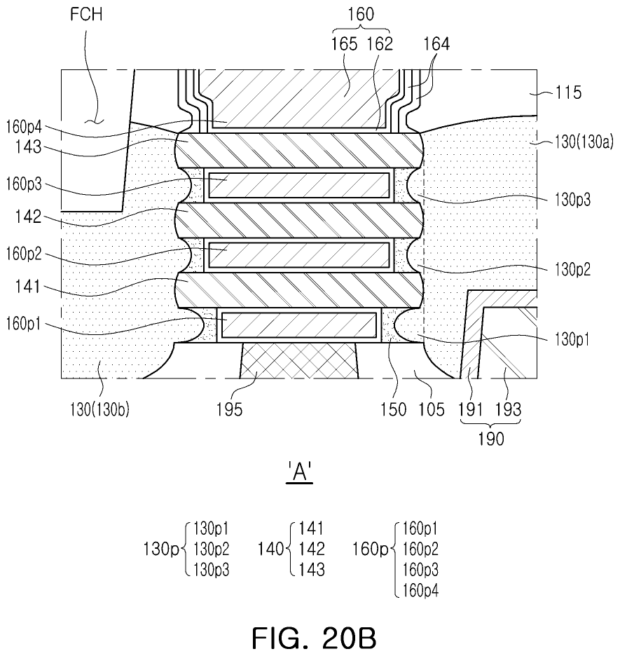

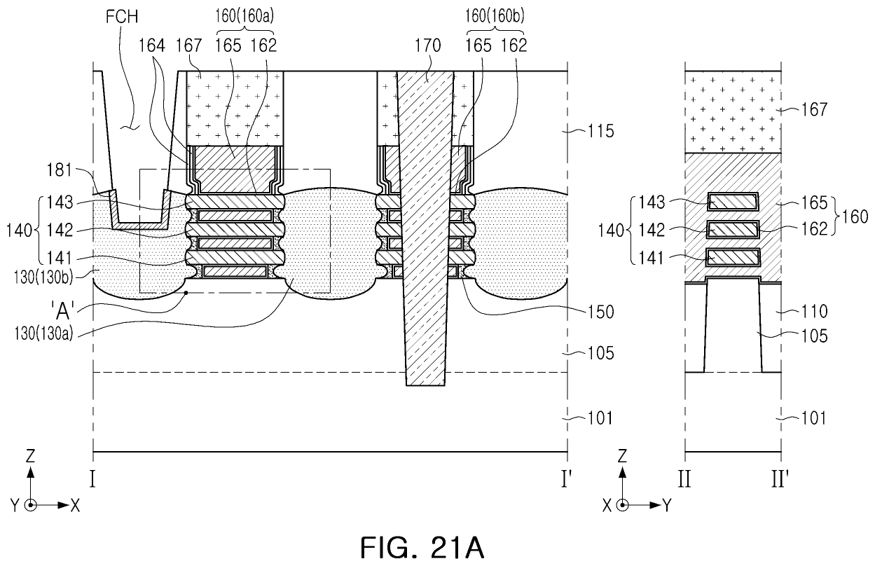

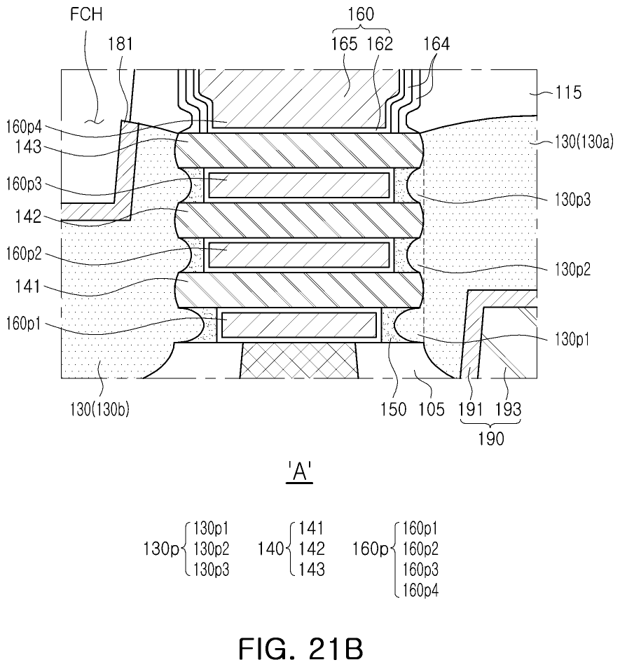

FIG. 15B, FIG. 16B, FIG. 20B, and FIG. 21B are partially enlarged views illustrated according to the process sequence to illustrate a method of manufacturing a semiconductor device according to example embodiments. FIG. 15B illustrates an enlarged view of region ‘A’ of FIG. 15A, FIG. 16B illustrates an enlarged view of region ‘A’ of FIG. 16B, FIG. 20B illustrates an enlarged view of region ‘A’ of FIG. 20A, and FIG. 21B illustrates an enlarged view of region ‘A’ of FIG. 21A.

Referring to FIG. 12, a plurality of sacrificial layers 120 and a plurality of channel layers 141, 142, and 143 may be alternately stacked on a substrate 101.

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The plurality of channel layers 140 may include a first channel layer 141, a second channel layer 142, and a third channel layer 143, and the plurality of sacrificial layers 120 may include a first sacrificial layer 121, a second sacrificial layer 122, and a third sacrificial layer 123. The plurality of sacrificial layers 120 may be replaced with gate dielectric layers 162 and gate electrodes 165 below the first channel layer 141, the second channel layer 142, and the third channel layer 143 through subsequent processes, as illustrated in FIG. 2. The first sacrificial layer 121 may be replaced with a first gate portion 160p1, the second sacrificial layer 122 may be replaced with a second gate portion 160p2, and the third sacrificial layer 123 may be replaced with a third gate portion 160p3. The plurality of sacrificial layers 120 may be formed of a material having etching selectivity with respect to the first channel layer 141, the second channel layer 142, and the third channel layer 143, respectively. The first channel layer 141, the second channel layer 142, and the third channel layer 143 may include a different material from the first sacrificial layer 121, the second sacrificial layer 122, and the third sacrificial layer 123. The first sacrificial layer 121, the second sacrificial layer 122, and the third sacrificial layer 123 and the first channel layer 141, the second channel layer 142, and the third channel layer 143 may include a semiconductor material, for example, including at least one of silicon (Si), silicon germanium (SiGe), or germanium (Ge), but may include different materials and may or may not include impurities. For example, the first sacrificial layer 121, the second sacrificial layer 122, and the third sacrificial layer 123 may include silicon germanium (SiGe), and the first channel layer 141, the second channel layer 142, and the third channel layer 143 may include silicon (Si). The concentrations of silicon (Si) and germanium (Ge) that may be included in the first sacrificial layer 121, the second sacrificial layer 122, and the third sacrificial layer 123 may be the same as or different from each other. In some example embodiments, the concentration of germanium (Ge) in the first sacrificial layer 121 may be greater than the concentrations of germanium (Ge) in the second sacrificial layer 122 and the third sacrificial layer 123, and in this case, the semiconductor device 100 of FIGS. 1 to 3 may be manufactured according to a subsequent process. The concentrations of germanium (Ge) in the second sacrificial layer 122 and the concentrations of germanium (Ge) in the third sacrificial layer 123 may be substantially the same as each other. In some example embodiments, the germanium (Ge) concentration of the first sacrificial layer 121 may be 30 atomic percentage (at %) to 35 at %, and the germanium (Ge) concentration of the second sacrificial layer 122 and the third sacrificial layer 123 may be 25 at % to 30 at %. In some example embodiments, the germanium (Ge) concentration of the second sacrificial layer 122 and the third sacrificial layer 123 may be 32 at % to 33 at %, and the germanium (Ge) concentration of the first sacrificial layer 121 may be 33 at % to 40 at %.

The plurality of sacrificial layers 120 and the first channel layer 141, the second channel layer 142, and the third channel layer 143 may be formed by performing an epitaxial growth process from the stack structure. The number of layers of channel layers alternately stacked with the sacrificial layers 120 may be variously changed in different embodiments.

Referring to FIG. 13, the plurality of sacrificial layers 120, the first channel layer 141, the second channel layer 142, and the third channel layer 143, and the substrate 101 may be partially removed to form an active structure including an active region 105, and a device isolating layer 110 may be formed.

The active structure may include an active region 105, a plurality of sacrificial layers 120, and the first channel layer 141, the second channel layer 142, and the third channel layer 143. The active structure may be formed in a line shape extending in one direction, for example, the X-direction, and may be spaced apart from an adjacent active structure in the Y-direction. Side surfaces of the active structure in the Y-direction may be coplanar with each other and may be disposed on a straight line.

In a region in which portions of each of the active region 105, the plurality of sacrificial layers 120 and the first channel layer 141, the second channel layer 142, and the third channel layer 143 are removed, a device isolating layer 110 may be formed by filling an insulating material and then removing a portion of the insulating material so that the active region 105 protrudes above the device isolating layer 110. An upper surface of the device isolating layer 110 may be formed to be lower in the Z-direction than an upper surface of the active region 105. The active region 105 may be formed as a portion of the substrate 101 or may include an epitaxial layer grown from the substrate 101.

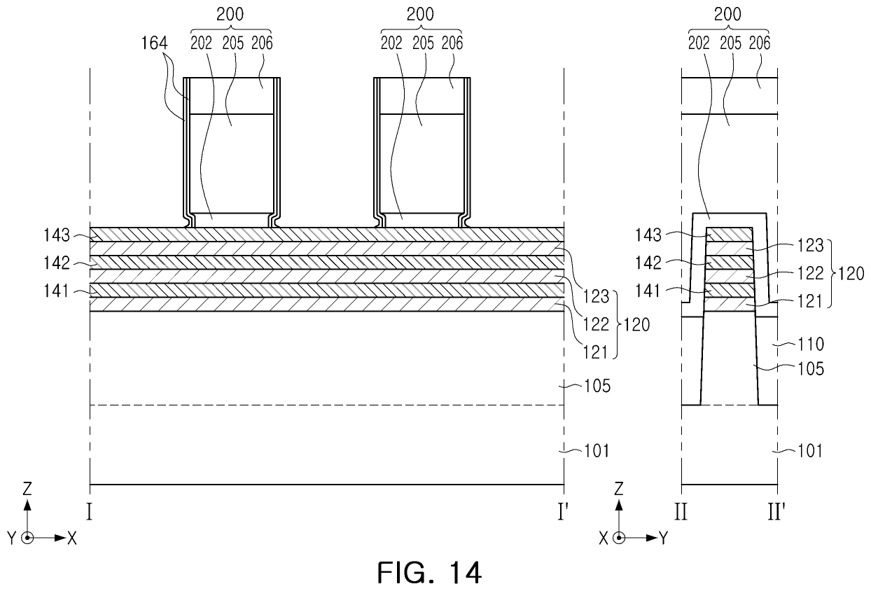

Referring to FIG. 14, sacrificial gate structures 200 and gate spacer layers 164 may be formed on the active structure.

Each of the sacrificial gate structures 200 may be a sacrificial structure formed in a region in which gate dielectric layers 162 and gate electrodes 165 are disposed on a channel structure 140 through a subsequent process, as illustrated in FIG. 2. The sacrificial gate structures 200 may have a line shape extending in one direction by intersecting the active structure. The sacrificial gate structures 200 may extend in the Y-direction. Each of the sacrificial gate structures 200 may include a first sacrificial gate layer 202, a second sacrificial gate layer 205, and a mask pattern layer 206 sequentially stacked in the Z-direction. The first sacrificial gate layer 202 and the second sacrificial gate layer 205 may be patterned using the mask pattern layer 206.

The first sacrificial gate layer 202 and the second sacrificial gate layer 205 may be an insulating layer and a conductive layer, respectively, but the present disclosure is not limited thereto. In some embodiments, the first sacrificial gate layer 202 and the second sacrificial gate layer 205 may be formed as a single layer. For example, the first sacrificial gate layer 202 may include silicon oxide and the second sacrificial gate layer 205 may include polysilicon. The mask pattern layer 206 may include silicon oxide and/or silicon nitride.

The gate spacer layers 164 may be formed on both sidewalls of the sacrificial gate structures 200. The first sacrificial gate layer 202 may be formed to have a smaller width than the second sacrificial gate layer 205, and the gate spacer layers 164 may be formed along sidewalls of the first sacrificial gate layer 202 and sidewalls of the second sacrificial gate layer 205. The gate spacer layers 164 may be made of a low-κ material, and may include, for example, at least one of SiO, SiN, SiCN, SiOC, SiON, or SiOCN.

Referring to FIGS. 15A and 15B, an etching process using the sacrificial gate structures 200 as an etching mask may be performed to form recessed regions RC penetrating through the active structure and exposing the active region 105.

Some of the sacrificial layers 120 and the first channel layer 141, the second channel layer 142, and the third channel layer 143 exposed from the sacrificial gate structures 200 may be removed to form recessed regions, and some of the plurality of sacrificial layers 120 may be removed. Accordingly, the first channel layer 141, the second channel layer 142, and the third channel layer 143 may form channel structures 140 having a length limited in the X-direction.

The plurality of sacrificial layers 120 may be partially etched not only in a region exposed from the sacrificial gate structures 200, but also in a region overlapping the sacrificial gate structures 200. The plurality of sacrificial layers 120 may include silicon germanium (SiGe) having the same or different compositions, and in some embodiments, a degree of removal of the sacrificial layers 120 in this operation may be identical or different. Depending on the concentration of germanium (Ge) included in each of the plurality of sacrificial layers 120, a degree of etching in the horizontal direction in this operation may vary. For example, a concentration of germanium (Ge) in the first sacrificial layer 121 may be greater than a concentration of germanium (Ge) included in the second sacrificial layer 122 and the third sacrificial layer 123, and a relatively larger amount thereof may be etched. The concentrations of germanium (Ge) in the second sacrificial layer 122 and the third sacrificial layer 123 may be substantially the same as each other, and the degrees to which the second sacrificial layer 122 and the third sacrificial layer 123 are etched in this operation may be substantially the same as each other. In some example embodiments, even if some of the plurality of sacrificial layers 120 have the same concentration of germanium (Ge), the degree to which the sacrificial layers 120 are etched in this operation may be reduced as the sacrificial layers 120 are disposed on a lower level in the Z-direction. For example, even if the concentrations of germanium (Ge) in the second sacrificial layer 122 and the third sacrificial layer 123 are the same, the second sacrificial layer 122 disposed on a lower level may be relatively less etched. Each of the plurality of sacrificial layers 120 may be etched differently in this operation, depending on the composition of added germanium (Ge), levels at which the sacrificial layers 120 are disposed, or the like, and thus, various types of semiconductor devices as well as the semiconductor devices of FIGS. 1 to 11 may be manufactured.

Referring to FIGS. 16A and 16B, a plurality of source/drain regions 130 may be formed in the recessed regions RC.

The source/drain regions 130 may be formed in the recessed regions RC, and may be grown and formed from side surfaces of the active regions 105 and the channel structures 140, for example, by a selective epitaxial process. Depending on the degree and shape of the etching of the first sacrificial layer 121, the second sacrificial layer 122, and the third sacrificial layer 123, the source/drain regions 130 may be formed to have the first protrusion portion 130p1, the second protrusion portion 130p2, and the third protrusion portion 130p3.

The source/drain regions 130 may include a plurality of epitaxial layers, and the epitaxial layers may have different non-silicon concentrations. The source/drain regions 130 may include impurities by in-situ doping, and may include a plurality of layers having different doping elements and/or different doping concentrations. In some example embodiments, the source/drain regions 130 may have an N-type conductivity, and may be formed to include at least one dopant among boron (B), gallium (Ga), and indium (In). In some example embodiments, the source/drain region 130 may have a P-type conductivity, and may be formed to include at least one dopant among phosphorus (P), arsenic (As), and antimony (Sb).

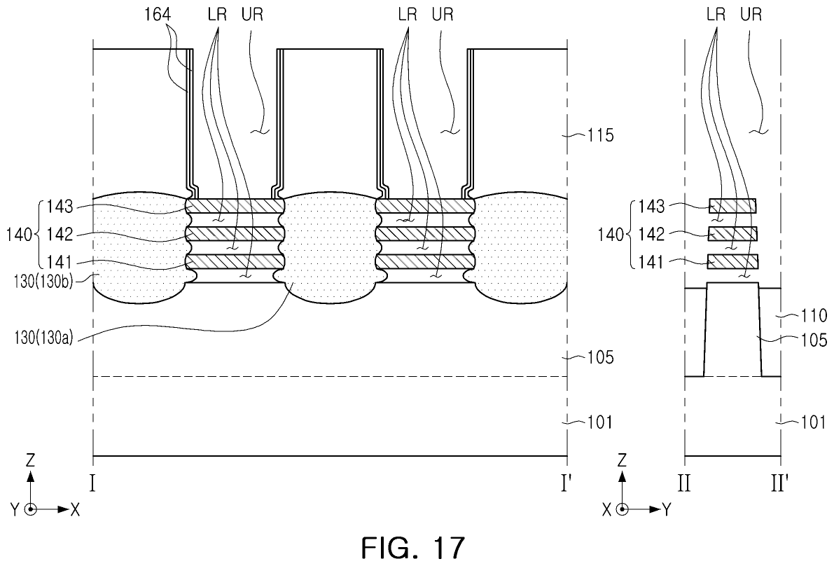

Referring to FIG. 17, the interlayer insulating layer 115 may be partially formed, and the sacrificial gate structures 200 and the plurality of sacrificial layers 120 may be removed.

The interlayer insulating layer 115 may be formed by forming an insulating film covering the sacrificial gate structures 200 and the source/drain regions 130 and performing a planarization process.

The sacrificial gate structures 200 and the plurality of sacrificial layers 120 may be selectively removed with respect to the gate spacer layers 164 and the channel structures 140. First, the sacrificial gate structures 200 may be removed to form upper gap regions UR, and then the sacrificial layers 120 exposed through the upper gap regions UR may be removed to form lower gap regions LR. For example, when the plurality of sacrificial layers 120 include silicon germanium (SiGe) and the channel structures 140 include silicon (Si), the plurality of sacrificial layers 120 may be selectively removed with respect to the channel structures 140 by performing a wet etching process.

Since the source/drain regions 130 include a lowermost protrusion portion 130p1 having a relatively large protrusion length, the lower gap region LR may be prevented from being generated in an inner region of the source/drain regions 130 in a process of removing the first sacrificial layer 121.

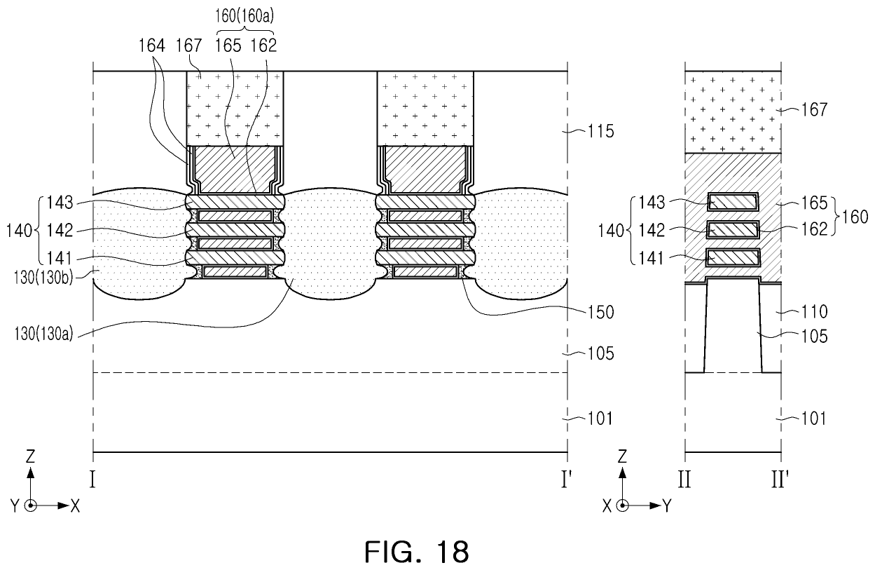

Referring to FIG. 18, internal spacers 150 may be formed, gate dielectric layers 162 and gate electrodes 165 may be formed to form gate structures 160, and gate capping layers 167 may be formed.

The internal spacers 150 may be formed to cover a plurality of protrusion portions 130p1, 130p2, and 130p3 of the source/drain regions 130 in the lower gap regions LR by depositing an insulating material in the lower gap regions LR and then partially etching the insulating material so that each of the plurality of channel layers 141, 142, and 143 is exposed to the lower gap regions LR.

The gate structures 160 may be formed to fill the upper gap regions UR and the lower gap regions LR. Portions filling the lower gap regions LR may form the first gate portion 160p1, the second gate portion 160p2, and the third gate portion 160p3, and first gate width G1, the second gate width G2, and the third gate width G3 may be formed to be substantially identical to or different from each other by the first protrusion portion 130p1, the second protrusion portion 130p2, and the third protrusion portion 130p3 and the internal spacers 150. A side surface of the fourth gate portion 160p4 filling the upper gap regions UR may be formed along the gate spacer layer 164, and may thus be formed to have a portion having the fourth gate width G4_2 and a portion having the recessed gate width G4_1. The gate dielectric layers 162 may be formed to conformally cover inner surfaces of the upper gap regions UR and the lower gap regions LR. After the gate electrode 165 is formed to completely fill the upper gap regions UR and the lower gap regions LR, the gate electrode 165 may be removed from the upper gap regions UR by a predetermined depth together with the gate dielectric layers 162 and the gate spacer layers 164. Accordingly, gate structures 160 respectively including the gate dielectric layers 162 and the gate electrode 165 may be formed.

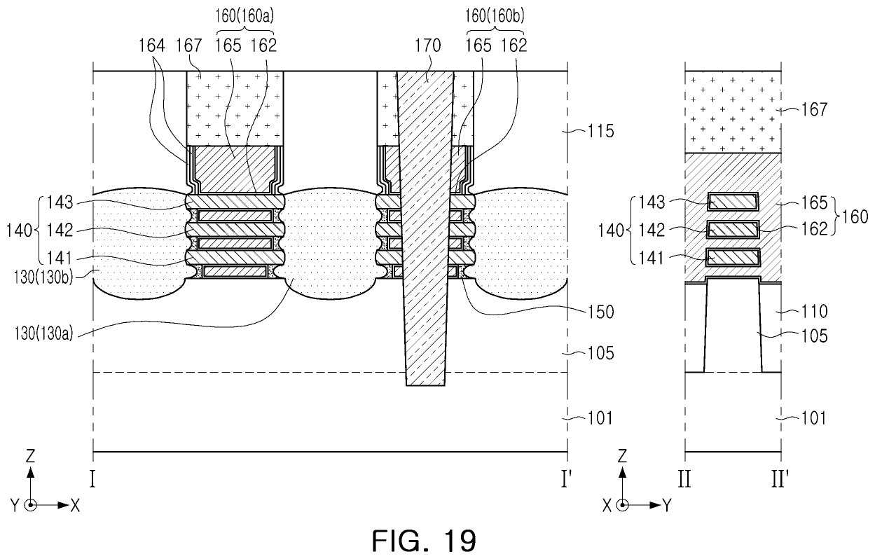

Referring to FIG. 19, a blocking structure 170 penetrating through one of the gate structures 160 may be formed.

The blocking structure 170 may penetrate through the second gate structure 160b and the active region 105 and may electrically and physically separate the second gate structure 160b and the active region 105 from each other. Adjacent transistors may be electrically separated by the blocking structure 170. The blocking structure 170 may extend into the interior of the substrate 101. In some example embodiments, an operation of forming the blocking structure 170 may be omitted.

Referring to FIG. 20A and FIG. 20B, a front contact hole FCH penetrating the interlayer insulating layer 115 and extending into the interior of the source/drain regions 130 may be formed.

In a region in which the frontside contact plug 180 (see FIG. 2) is to be formed, the contact hole FCH may be formed by etching the interlayer insulating layer 115 from an upper portion thereof, and recessing exposed source/drain regions 130 from an upper surface thereof. A lower end of the contact hole FCH may be formed on a level in the Z-direction lower than that of a lower surface of the third channel layer 143, and may be formed on a level lower than that of a lower surface of the third gate portion 160p3, according to an example embodiment.

Referring to FIGS. 21A and 21B, a front metal-semiconductor compound layer 181 may be formed on the source/drain regions 130 exposed by the front contact hole FCH.

The front metal-semiconductor compound layer 181 may be formed by depositing a metal layer at a relatively high temperature, for example, about 400° C. to about 500° C., and simultaneously allowing the metal layer to react with the source/drain regions 130. The front metal-semiconductor compound layer 181 may be formed to partially include materials of the source/drain region 130 exposed by the front contact hole FCH, and may thus be formed in an expanded form centered on boundaries of the front contact hole FCH. In some example embodiments, when third protrusion length P3 of an uppermost protrusion portion 130p3 is formed to be relatively long, a space of the front metal-semiconductor compound layer 181 may be stably secured.

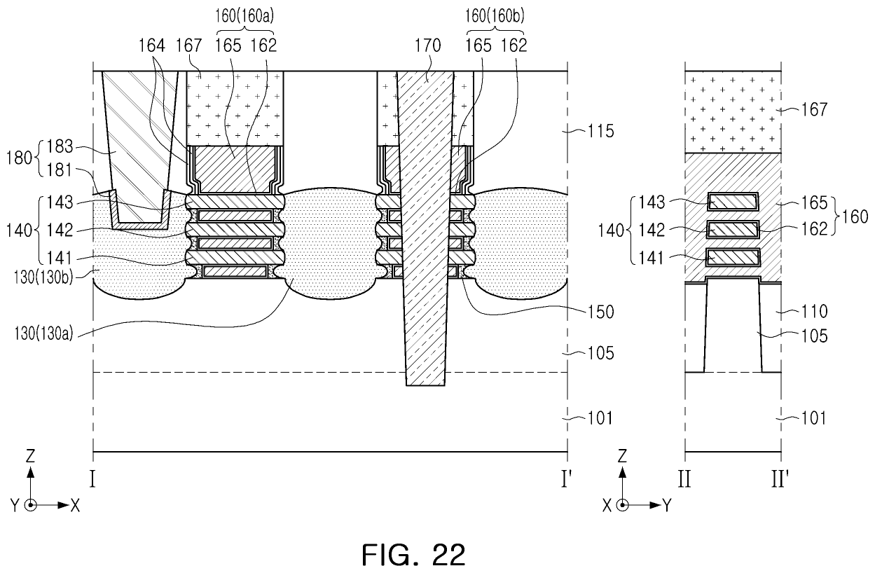

Referring to FIG. 22, a front contact conductive layer 183 may be formed to fill the front contact hole FCH on the front metal-semiconductor compound layer 181, and a frontside contact plug 180 may be formed.

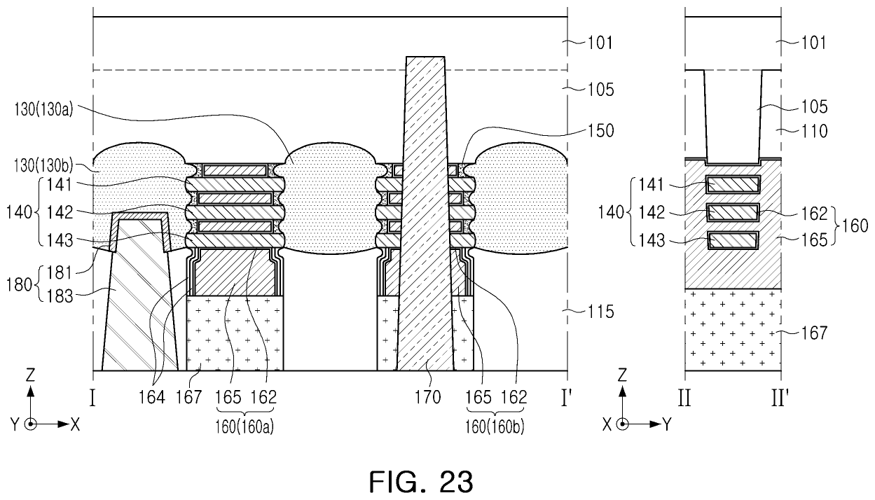

Referring to FIG. 23, the substrate 101 may be partially removed.

To perform a process from a lower surface of the substrate 101 of FIG. 22, a separate carrier substrate may be formed on the interlayer insulating layer 115 and the entire structure may be turned over to perform the following processes. The substrate 101 may be thinned by removing a portion of the substrate 101, for example, in a lapping, grinding, and/or polishing process. In some example embodiments, the active region 105 and the device isolating layer 110 may be partially removed. In some example embodiments, the substrate 101 and the active region 105 may be completely removed, and when the substrate 101 and the active region 105 may be replaced with an insulating layer, a semiconductor device 100H of FIG. 11 including the substrate insulating layer 196 may be manufactured.

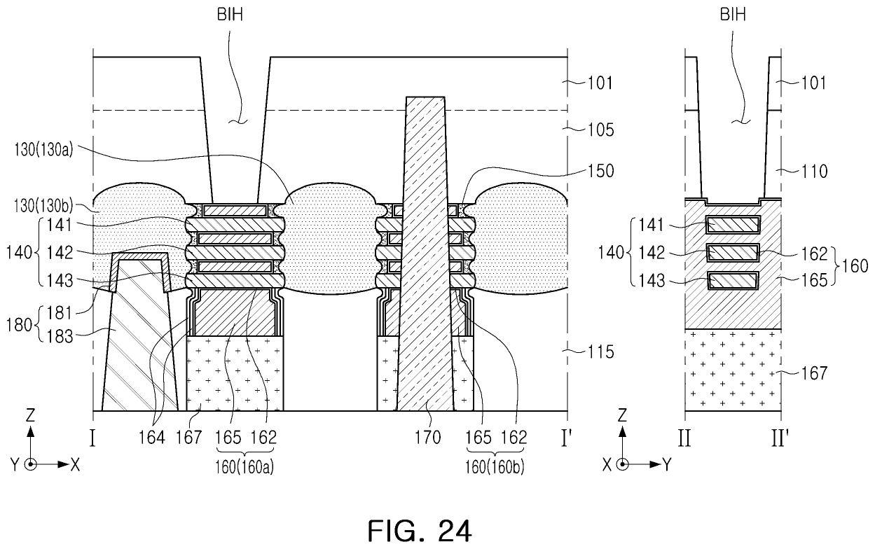

Referring to FIG. 24, a separation hole BIH penetrating through the substrate 101 and the active region 105 may be formed.

The separation hole BIH may be formed to expose the gate structure 160, and thus the gate dielectric layer 162 of the gate structure 160 may be exposed. The active region 105 may be separated by the separation hole BIH.

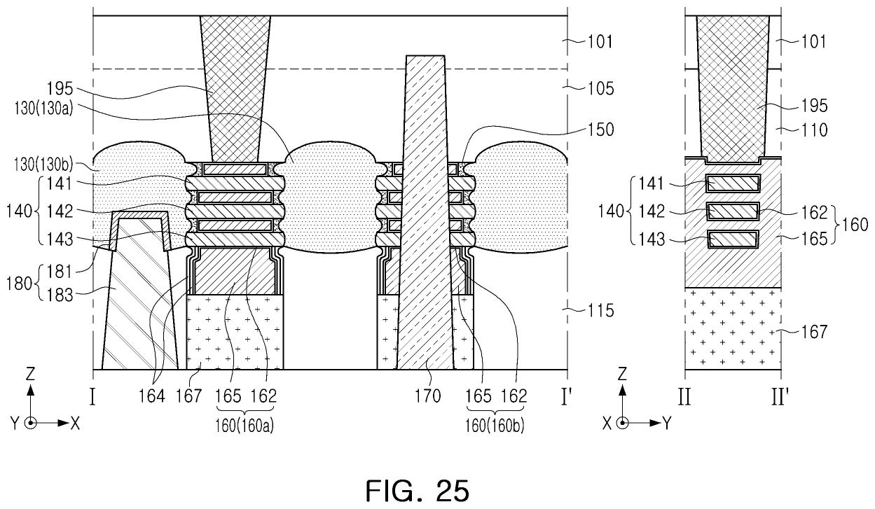

Referring to FIG. 25, a lower separation structure 195 may be formed to fill the separation hole BIH. In some example embodiments, the lower separation structure 195 may be formed by depositing an insulating material in the separation hole BIH.

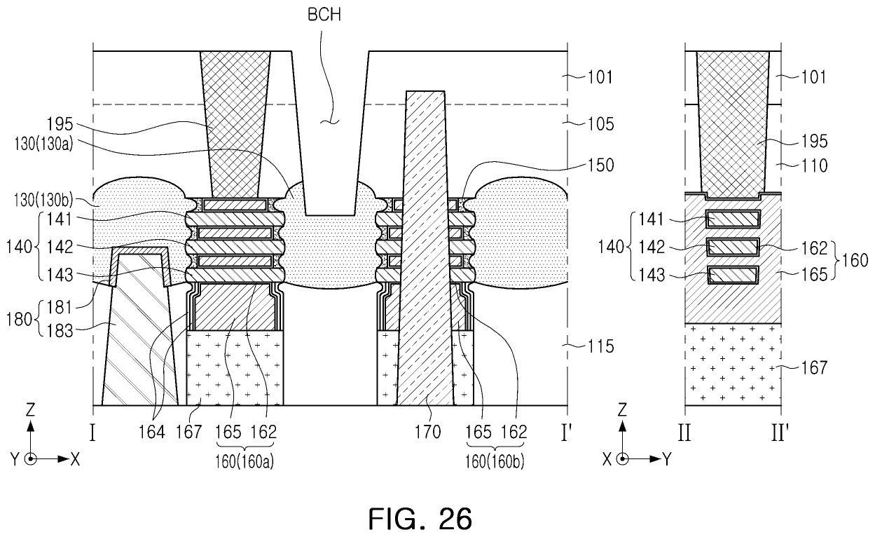

Referring to FIG. 26, a back contact hole BCH penetrating through the substrate 101 and the active region 105 may be formed.

The back contact hole BCH may be formed to recess the source/drain region 130 from an upper portion (based on FIG. 26) by penetrating through the substrate 101 and the active region 105. A lower end of the back contact hole FCH may be formed on a level in the Z-direction lower than that of an upper surface of the first channel layer 141.

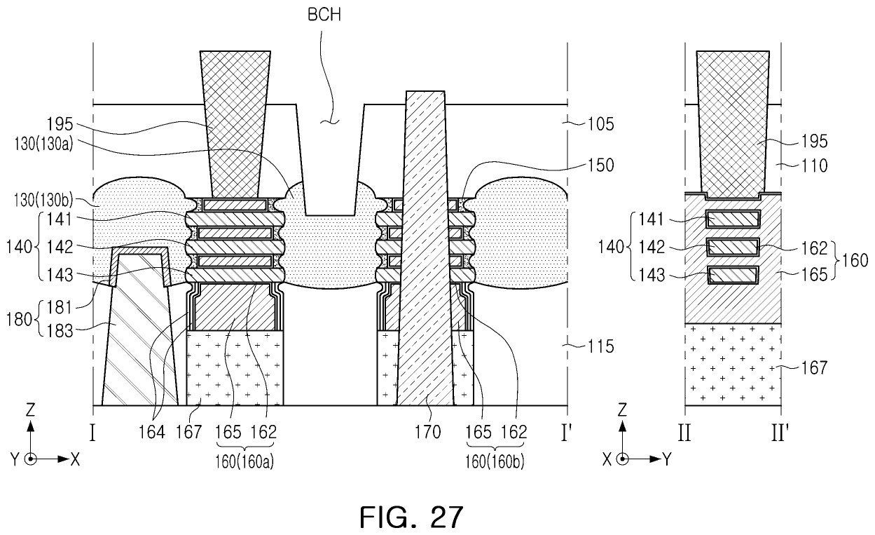

Referring to FIG. 27, the substrate 101, the active region 105, and the device isolating layer 110 may be partially removed.

The substrate 101, the active region 105, and the device isolating layer 110 may be partially removed in a lapping, grinding, and/or polishing process and may thus be thinned, or may be partially removed by a manner such as a wet etching or dry etching process, and the blocking structure 170 may be partially exposed. In this operation, a side surface of the lower separation structure 195 may be exposed.

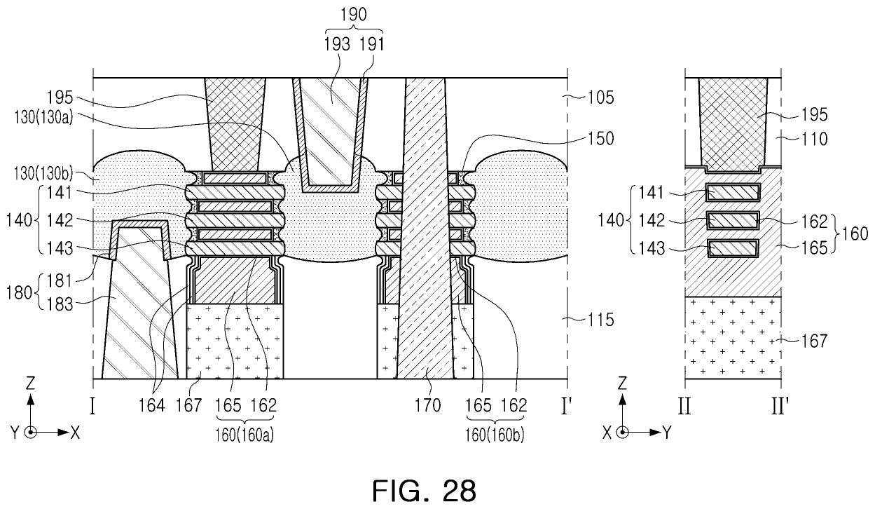

Referring to FIG. 28, a backside contact plug 190 may be formed.

A back metal-semiconductor compound layer 191 may be formed on the source/drain region 130 and the active region 105 exposed by the back contact hole BCH. The back metal-semiconductor compound layer 191 may be formed in a manner identical to or similar to a formation manner of the front metal-semiconductor compound layer 181. However, unlike the front metal-semiconductor compound layer 181, the back metal-semiconductor compound layer 191 may be formed not only in the source/drain region 130 but also in the active region 105. In some example embodiments, a process, such as a process of forming an insulating liner, may be added so that the back metal-semiconductor compound layer 191 may be not formed on the active region 105. In some example embodiments, referring to FIGS. 2 and 3 together, when the first protrusion length P1 of the lowermost protrusion portion 130p1 is formed to be relatively long, a space of the back metal-semiconductor compound layer 191 may be stably secured.

A back contact conductive layer 193 may be formed to fill the back contact hole BCH on a back metal-semiconductor compound layer 191, and a backside contact plug 190 may be formed.

Then, the backside contact plug 190, the active region 105, the device isolating layer 110, and the lower separation structure 195 may be recessed from an upper surface based on FIG. 28, so that upper surfaces thereof may be coplanar with each other.

Then, referring to FIG. 2 together, a lower insulating layer 197 covering lower surfaces of each of the backside contact plug 190, the active region 105, the device isolating layer 110, and the lower separation structure 195 may be formed, and a backside power structure 198 penetrating through the lower insulating layer 197 and connected to the backside contact plug 190 may be formed, and the semiconductor device 100 of FIGS. 1 to 3 may be manufactured.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
an active region extending in a first direction;
a gate structure disposed on the active region, the gate structure extending in a second direction perpendicular to the first direction;
a first source/drain region and a second source/drain region disposed on opposite sides of the gate structure along the first direction;
a plurality of channel layers disposed spaced apart from each other in a vertical direction that is perpendicular to the first direction and the second direction, the plurality of channel layers including a first channel layer, a second channel layer, and a third channel layer arranged sequentially along the vertical direction, each of the plurality of channel layers being surrounded by the gate structure in a plane perpendicular to the first direction;
a first contact plug electrically connected to the first source/drain region; and
a second contact plug electrically connected to the second source/drain region,
wherein each of the first source/drain region and the second source/drain region includes a plurality of protrusion portions comprising:
a first protrusion portion disposed below the first channel layer, the first protrusion portion extending toward the gate structure along the first direction,
a second protrusion portion disposed below the second channel layer, the second protrusion extending toward the gate structure along the first direction, and
a third protrusion portion disposed below the third channel layer, the third protrusion extending toward the gate structure along the first direction, and
wherein
a first distance along the first direction between the first protrusion portion of the first source/drain region and the first protrusion portion of the second source/drain region is less than a second distance along the first direction between the second protrusion portion of the first source/drain region and the second protrusion portion of the second source/drain region, and
the first distance is less than a third distance along the first direction between the third protrusion portion of the first source/drain region and the third protrusion portion of the second source/drain region.

2. The semiconductor device of claim 1, wherein at least one of the plurality of protrusion portions of each of the first source/drain region and the second source/drain region includes a portion along the first direction that overlaps the gate structure in the vertical direction.

3. The semiconductor device of claim 1, wherein the first distance is a shortest distance between the first source/drain region and the second source/drain region, among the first distance, the second distance, and the third distance.

4. The semiconductor device of claim 1, wherein the third distance is less than the second distance.

5. The semiconductor device of claim 1, wherein a first difference between the second distance and the third distance is less than a second difference between the first distance and the second distance.

6. The semiconductor device of claim 1, wherein a third difference between the second distance and the third distance is less than a fourth difference between the first distance and the third distance.

7. The semiconductor device of claim 1, extending in the vertical direction from a lower portion to an upper portion, wherein the first contact plug is a backside contact plug extending in the vertical direction from the lower portion of the semiconductor device towards the upper portion of the semiconductor device, the first contact plug extending through the active region and partially through the first source/drain region to an upper end of the first contact plug, the first contact plug disposed in a first recess extending through the active region and partially through the first source/drain region.

8. The semiconductor device of claim 7, wherein the second contact plug is a frontside contact plug extending in the vertical direction from the upper portion of the semiconductor device towards the lower portion of the semiconductor device, the second contact plug extending through an interlayer insulting layer and partially through the second source/drain region, the second contact plug disposed in a second recess extending through the interlayer insulating layer and partially through the second source/drain region.

9. The semiconductor device of claim 7, wherein the first contact plug includes a metal-semiconductor compound layer disposed along a surface of the first recess and a contact conductive layer disposed on the metal-semiconductor compound layer.

10. The semiconductor device of claim 9, wherein the upper end of the first contact plug is disposed along the vertical direction at a first level higher than a second level of the first protrusion portion relative to the lower portion of the semiconductor device.

11. The semiconductor device of claim 1, wherein:
the first contact plug penetrates through the first source/drain region and the active region.

12. The semiconductor device of claim 1, extending in the vertical direction from a lower portion to an upper portion and further comprising:
a lower separation structure extending in the vertical direction from the lower portion of the semiconductor device towards the upper portion of the semiconductor device, the lower separation structure extending through the active region, the gate structure is disposed on the lower separation structure, and the gate structure is in contact with the lower separation structure.

13. The semiconductor device of claim 1, wherein the gate structure includes:
a gate electrode surrounding each of the plurality of channel layers in the plane perpendicular to the second direction; and
a gate dielectric layer disposed between the gate electrode and each of the plurality of channel layers; and
the gate structure has a gate portion disposed on the third channel layer, the gate portion having a gate structure width that is narrower in the first direction than a width of the third channel layer.

14. A semiconductor device, comprising:
a gate structure;
a plurality of channel layers disposed spaced apart from each other in a vertical direction, the plurality of channel layers including a lowermost channel layer, an intermediate channel layer, and an uppermost channel layer arranged sequentially in the vertical direction, each of the plurality of channel layers being surrounded by the gate structure; and
a source/drain region on one side of the gate structure and connected to the plurality of channel layers,
wherein the source/drain region includes a plurality of protrusion portions including:
a lowermost protrusion portion extending in a first horizontal direction toward the gate structure, the lowermost protrusion portion disposed below the lowermost channel layer;
an intermediate protrusion portion extending in the first horizontal direction, the intermediate protrusion portion disposed between the lowermost channel layer and the intermediate channel layer; and
an uppermost protrusion portion extending in the first horizontal direction, the uppermost protrusion portion disposed between the intermediate channel layer and the uppermost channel layer; and
a first width of the lowermost protrusion portion in the first horizontal direction is greater than a second width of the intermediate protrusion portion in the first horizontal direction.

15. The semiconductor device of claim 14, wherein the first width is greater than a third width of the uppermost protrusion portion in the first horizontal direction.

16. The semiconductor device of claim 14, further comprising:
internal spacers disposed between each of the plurality of protrusion portions and the gate structure along the first horizontal direction.

17. A semiconductor device, comprising:
a gate structure;
a plurality of channel layers including a first channel layer, a second channel layer, and a third channel layer arranged sequentially in a vertical direction, an uppermost channel layer being disposed adjacent to the gate structure, each of the plurality of channel layers being surrounded by the gate structure;
a source/drain region on at least one side of the gate structure and connected to the plurality of channel layers; and
a backside contact plug connected to the source/drain region,
wherein the gate structure includes:
a first gate portion disposed below the first channel layer in the vertical direction;
a second gate portion disposed between the first channel layer and the second channel layer in the vertical direction;
a third gate portion disposed between the second channel layer and the third channel layer in the vertical direction; and
a fourth gate portion disposed on the third channel layer in the vertical direction,
wherein a first gate width of the first gate portion in a first direction perpendicular to the vertical direction is less than a second gate width of the second gate portion in the first direction and a third gate width of the third gate portion in the first direction, respectively.

18. The semiconductor device of claim 17, wherein:
the fourth gate portion includes a lower portion and an upper portion disposed above the lower portion in the vertical direction;
the upper portion has a fourth gate width in the first direction; and
the lower portion has a fifth gate width in the first direction, the fifth gate width being less than the fourth gate width.

19. The semiconductor device of claim 17, wherein:
the source/drain region includes:
a first protrusion portion disposed at a same first level relative to the lower portion of the semiconductor device along the vertical direction as the first gate portion, the first protrusion portion extending toward the first gate portion in the first direction;
a second protrusion portion disposed at a same second level relative to the lower portion of the semiconductor device along the vertical direction as the second gate portion, the second protrusion portion extending toward the second gate portion in the first direction; and
a third protrusion portion disposed at a same third level relative to the lower portion of the semiconductor device along the vertical direction as the third gate portion, the third protrusion extending toward the third gate portion in the first direction; and
a first length of the first protrusion portion in the first direction is greater than a second length of the second protrusion portion in the first direction.

20. The semiconductor device of claim 19, wherein the first length is greater than a third length of the third protrusion portion in the first direction.
